(19) United States
(12) Patent Application Publication
(10) Pub. No.: US 2026/0096000 A1
(43) Pub. Date: Apr. 2, 2026

(54) EXTREME ULTRAVIOLET LIGHT GENERATION SYSTEM AND ELECTRONIC DEVICE MANUFACTURING METHOD

(71) Applicant: Gigaphoton Inc., Oyama-shi (JP)

(72) Inventor: Kotaro MIYASHITA, Oyama-shi (JP)

(73) Assignee: Gigaphoton Inc., Oyama-shi (JP)

(21) Appl. No.: 19/321,802

(22) Filed: Sep. 8, 2025

(30) Foreign Application Priority Data
Oct. 2, 2024 (JP) 2024-173876

(51) Int. Cl. H05G 2/00; G01N 21/95; G03F 1/22; G03F 7/00

(52) U.S. Cl. CPC H05G 2/0027; G01N 21/9501; G03F 1/22; G03F 7/70033; H05G 2/0084

(57) ABSTRACT

An extreme ultraviolet light generation system, generating plasma by irradiating a target with pulse laser light and generate extreme ultraviolet light, includes a chamber, a target supply unit supplying the target into the chamber, a target passage detection device detecting the target passing through a predetermined region, a laser device radiating the pulse laser light toward the target having passed through the predetermined region, and a processor. The target passage detection device includes a light source irradiating the predetermined region with light, and a sensor receiving the light and outputting a signal corresponding to a received light amount of the light. The processor acquires, from the signal, a passage timing at which the target is detected and a time width during which the target is detected, and determines irradiation timing of the laser device for irradiating with the pulse laser light based on the passage timing and the time width.

### CROSS-REFERENCE TO RELATED APPLICATIONS

The present application claims the benefit of Japanese Patent Application No. 2024/173876, filed on Oct. 2, 2024, the entire contents of which are hereby incorporated by reference.

### BACKGROUND

### 1. Technical Field

The present disclosure relates to an extreme ultraviolet light generation system and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: International Publication No. WO2016/079810
Patent Document 2: International Publication No. WO2016/013102
Patent Document 3: International Publication No. WO2016/170658
Patent Document 4: Japanese Patent Application Publication No. 2006-23275

### SUMMARY

An extreme ultraviolet light generation system, according to an aspect of the present disclosure, is configured to generate plasma by irradiating a target with pulse laser light and generate extreme ultraviolet light, and includes a chamber, a target supply unit configured to supply the target into the chamber, a target passage detection device configured to detect the target passing through a predetermined region, a laser device configured to radiate the pulse laser light toward the target having passed through the predetermined region, and a processor. Here, the target passage detection device includes a light source configured to irradiate the predetermined region with light, and a sensor configured to receive the light and output a signal corresponding to a received light amount of the light. The processor acquires, from the signal, a passage timing at which the target is detected and a time width during which the target is detected, and determines irradiation timing of the laser device for irradiating with the pulse laser light based on the passage timing and the time width.

An electronic device manufacturing method according to an aspect of the present disclosure includes generating extreme ultraviolet light using an extreme ultraviolet light generation system, outputting the extreme ultraviolet light to an exposure apparatus, and exposing a photosensitive substrate to the extreme ultraviolet light in the exposure apparatus to manufacture an electronic device. Here, the extreme ultraviolet light generation system is configured to generate plasma by irradiating a target with pulse laser light and generate the extreme ultraviolet light. The extreme ultraviolet light generation system includes a chamber, a target supply unit configured to supply the target into the chamber, a target passage detection device configured to detect the target passing through a predetermined region, a laser device configured to radiate the pulse laser light toward the target having passed through the predetermined region, and a processor. The target passage detection device includes a light source configured to irradiate the predetermined region with light, and a sensor configured to receive the light and output a signal corresponding to a received light amount of the light. The processor acquires, from a signal, a passage timing at which the target is detected and a time width during which the target is detected, and determines irradiation timing of a laser device for irradiating with pulse laser light based on the passage timing and the time width.

An electronic device manufacturing method according to an aspect of the present disclosure includes inspecting a defect of a mask by irradiating the mask with extreme ultraviolet light generated by an extreme ultraviolet light generation system, selecting a mask using a result of the inspection, and exposing and transferring a pattern formed on the selected mask onto a photosensitive substrate. Here, the extreme ultraviolet light generation system is configured to generate plasma by irradiating a target with pulse laser light and generate the extreme ultraviolet light. The extreme ultraviolet light generation system includes a chamber, a target supply unit configured to supply the target into the chamber, a target passage detection device configured to detect the target passing through a predetermined region, a laser device configured to radiate the pulse laser light toward the target having passed through the predetermined region, and a processor. The target passage detection device includes a light source configured to irradiate the predetermined region with light, and a sensor configured to receive the light and output a signal corresponding to a received light amount of the light. The processor acquires, from a signal, a passage timing at which the target is detected and a time width during which the target is detected, and determines irradiation timing of a laser device for irradiating with pulse laser light based on the passage timing and the time width.

### BRIEF DESCRIPTION OF THE DRAWINGS

Embodiments of the present disclosure will be described below merely as examples with reference to the accompanying drawings.

FIG. 1 schematically shows the configuration of an LPP EUV light generation system.

FIG. 2 shows the configuration of an EUV light generation apparatus according to a comparative example.

FIG. 3 shows an example of a PDA module.

FIG. 4 shows an example of a detection signal output from a target passage detection device and an example of a target detection trigger signal generated from the detection signal.

FIG. 5 shows an example of a generation timing of each trigger signal generated by a trigger selection and delay device of the comparative example.

FIG. 6 shows an example of the generation timing of each trigger signal generated by the trigger selection and delay device of the comparative example.

FIG. 7 schematically shows an example of an image acquired via an image sensor of the comparative example.

FIG. 8 is a timing chart showing the generation timing of each trigger signal whose delay time has been corrected.

FIG. 9 shows the generation timing of each trigger signal generated by the trigger selection and delay device of the comparative example.

FIG. 10 shows the configuration of the EUV light generation apparatus according to a first embodiment.

FIG. 11 is an explanatory diagram showing a calculation method of a timing correction amount Δtad of the first embodiment.

FIG. 12 shows the generation timing of each trigger signal generated by the trigger selection and delay device of the first embodiment.

FIG. 13 is an explanatory diagram of operation of a pulse waveform processing unit of the first embodiment.

FIG. 14 is a flowchart showing an example of operation related to timing correction of each trigger signal in the EUV light generation apparatus according to the first embodiment.

FIG. 15 is a flowchart of a subroutine of update processing of each delay time applied to step S15 of FIG. 14.

FIG. 16 is an explanatory diagram of the update processing of a velocity coefficient in the EUV light generation apparatus according to a second embodiment.

FIG. 17 is a flowchart showing an example of operation related to timing correction of each trigger signal in the EUV light generation apparatus according to the second embodiment.

FIG. 18 is a flowchart showing a subroutine of the update processing of the velocity coefficient applied to step S26 of FIG. 17.

FIG. 19 shows the configuration of the EUV light generation apparatus according to a third embodiment.

FIG. 20 is an explanatory diagram of various parameters used in the EUV light generation apparatus according to the third embodiment.

FIG. 21 is a flowchart showing flow of database creation processing according to the third embodiment.

FIG. 22 is a flowchart showing an example of the update processing of each delay time of the corresponding trigger signal performed at the time of EUV light emission according to the third embodiment.

FIG. 23 is a table showing an example of a database FIG. 24 is a table showing an example of the database.

FIG. 25 is a table showing an example of the database FIG. 26 is an explanatory diagram of a usage example of the database shown in FIGS. 23 to 25.

FIG. 27 is an explanatory diagram of a target detection signal obtained by coupling outputs of two adjacent sensor elements.

FIG. 28 schematically shows the configuration of an exposure apparatus connected to the EUV light generation apparatus.

FIG. 29 schematically shows the configuration of an inspection apparatus connected to the EUV light generation apparatus.

### DESCRIPTION OF EMBODIMENTS

### Contents

1. Description of terms
2. Overall description of EUV light generation system
   2.1 Configuration
   2.2 Operation
3. EUV light generation apparatus according to comparative example
   3.1 Configuration
   3.2 Operation
4. Problem
5. First Embodiment
   5.1 Configuration
   5.2 Operation
   5.3 Relationship between detection signal obtained from target passage detection device and threshold
   5.4 Effect
6. Second Embodiment
   6.1 Configuration
   6.2 Operation
   6.3 Effect
7. Third Embodiment
   7.1 Configuration
   7.2 Operation
      7.2.1 Creation of database
      7.2.2 Operation for EUV light emission
      7.2.3 Specific example
   7.3 Effect
8. Fourth Embodiment
   8.1 Configuration
   8.2 Operation
   8.3 Effect
9. Electronic device manufacturing method
10. Processor
11. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Terms

A “target” is an object to be irradiated with laser light introduced into a chamber. The target irradiated with laser light is turned into plasma and emits EUV light.

A “droplet” is a form of a target supplied into the chamber.

“Plasma light” is radiation light radiated from a target turned into plasma. The radiation light includes EUV light.

### 2. Overall Description of EUV Light Generation System

### 2.1 Configuration

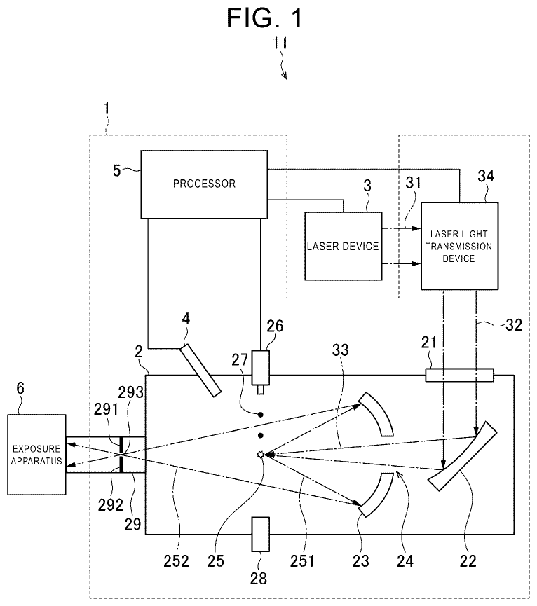

FIG. 1 schematically shows the configuration of an LPP EUV light generation system 11. An EUV light generation apparatus 1 is used together with a laser device 3. In the present disclosure, a system including the EUV light generation apparatus 1 and the laser device 3 is referred to as the EUV light generation system 11.

The EUV light generation apparatus 1 includes a chamber 2 and a target supply unit 26. The chamber 2 is a sealable container. A target supply unit 26 supplies a target substance into the chamber 2. The material of the target substance may include tin, terbium, gadolinium, lithium, xenon, or a combination of any two or more thereof.

A through hole is formed in a wall of the chamber 2. The through hole is blocked by a window 21 through which pulse laser light 32 output from the laser device 3 passes. An EUV light concentrating mirror 23 having a spheroidal reflection surface is arranged in the chamber 2. The EUV light concentrating mirror 23 has a first focal point and a second focal point. A multilayer reflection film in which molybdenum and silicon are alternately stacked is formed on a surface of the EUV light concentrating mirror 23. The EUV light concentrating mirror 23 may be arranged so that the first focal point is located in a plasma generation region 25 and the second focal point is located at an intermediate focal point 292. A through hole 24 is formed at the center of the EUV light concentrating mirror 23, and pulse laser light 33 passes through the through hole 24.

The EUV light generation apparatus 1 includes a processor 5, a target sensor 4, and the like. The target sensor 4 detects at least one of the presence, trajectory, position, and velocity of the target 27. The target sensor 4 may have an imaging function.

Further, the EUV light generation apparatus 1 includes a connection portion 29 providing communication between the internal space of the chamber 2 and the internal space of the exposure apparatus 6. A wall 291 in which an aperture 293 is formed is provided in the connection portion 29. The wall 291 is arranged so that the aperture 293 is located at the second focal point of the EUV light concentrating mirror 23.

Further, the EUV light generation apparatus 1 includes a laser light transmission device 34, a laser light concentrating mirror 22, a target collection device 28 for collecting the target 27, and the like. The laser light transmission device 34 includes an optical element for defining a transmission state of laser light, and an actuator for adjusting the position, posture, and the like of the optical element.

### 2.2 Operation

Operation of the EUV light generation system 11 will be described with reference to FIG. 1. Pulse laser light 31 output from the laser device 3 enters, via the laser light transmission device 34, the chamber 2 through the window 21 as the pulse laser light 32. The pulse laser light 32 travels along a laser light path in the chamber 2, is reflected by the laser light concentrating mirror 22, and is radiated to the target 27 as the pulse laser light 33.

The target supply unit 26 outputs the target 27 formed of a target substance toward the plasma generation region 25 in the chamber 2. The target 27 is irradiated with the pulse laser light 33. The target 27 irradiated with the pulse laser light 33 is turned into plasma, and radiation light 251 is radiated from the plasma. EUV light 252 contained in the radiation light 251 is selectively reflected by the EUV light concentrating mirror 23. The EUV light 252 reflected by the EUV light concentrating mirror 23 is concentrated at the intermediate focal point 292 and output to the exposure apparatus 6. Here, one target 27 may be irradiated with a plurality of pulses included in the pulse laser light 33.

The processor 5 is configured to control the entire EUV light generation system 11. The processor 5 processes image data or the like of the target 27 captured by the target sensor 4. The processor 5 performs, for example, at least one of control of the timing at which the target 27 is output and control of the output direction and the like of the target 27. Further, the processor 5 performs, for example, at least one of control of the oscillation timing of the laser device 3, control of the travel direction of the pulse laser light 32, and control of the concentration position of the pulse laser light 33. The above-described various kinds of control are merely examples, and other control may be added as necessary.

### 3. EUV Light Generation Apparatus According to Comparative Example

### 3.1 Configuration

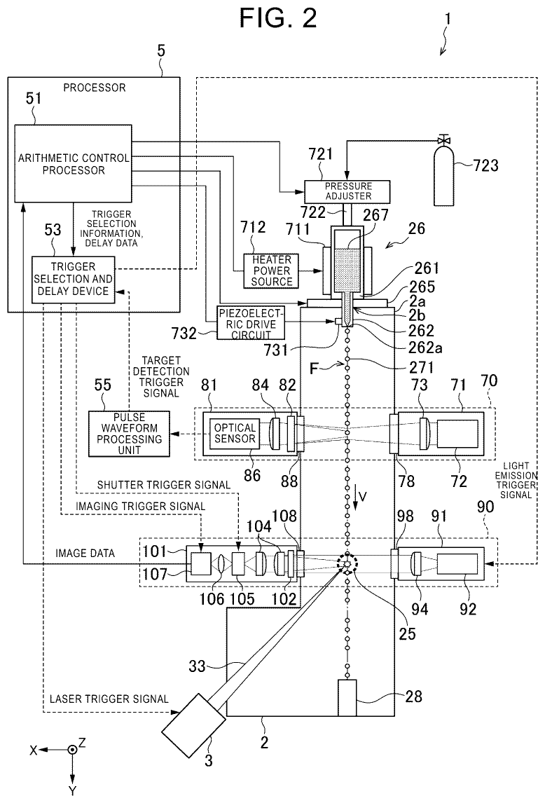

The configuration of the EUV light generation apparatus 1 according to the comparative example will be described using FIG. 2. The comparative example of the present disclosure is an example recognized by the applicant as known only by the applicant, and is not a publicly known example admitted by the applicant.

In FIG. 2, the direction in which the EUV light 252 is introduced from the chamber 2 of the EUV light generation apparatus 1 toward the exposure apparatus 6 (not shown in FIG. 2) is defined as a Z axis. An X axis and a Y axis are orthogonal to the Z axis and orthogonal to each other. In the subsequent drawings, the same coordinate axes as those introduced in FIG. 2 are used.

The chamber 2 is formed in a hollow spherical shape or a cylindrical shape, for example. The center axis direction of the cylindrical chamber 2 may be the Z-axis direction. In FIG. 2, illustration of the laser light concentrating mirror 22 (see FIG. 1) is omitted, and a state in which the pulse laser light 33 output from the laser device 3 is radiated toward the plasma generation region 25 is described for convenience. The description in FIG. 1 is not a description for specifying the irradiation direction of the pulse laser light 33. The irradiation direction of the pulse laser light 33 may be the Z-axis direction.

The chamber 2 is provided with a target supply path 2a for supplying the target 27 from outside the chamber 2 into the chamber 2. The target supply path 2a is formed into a cylindrical shape. The center axis direction of the cylindrical target supply path 2a may be substantially perpendicular to the Z axis. The center axial direction of the target supply path 2a shown in FIG. 2 is the Y direction.

When the chamber 2 has a hollow spherical shape, the target supply path 2a may be provided in a wall portion of the chamber 2 at a position where the window 21 and the connection portion 29 are not arranged. The target supply path 2a communicating with the chamber 2 may be understood as a part of the chamber 2, and the inside of the target supply path 2a is understood as the inside of the chamber 2.

The target supply unit 26 is arranged at an end of the target supply path 2a in the Y direction (an upper end in the Y direction in FIG. 2). The target supply unit 26 includes a tank 261, a nozzle 262, and a piezoelectric element 731. The tank 261 is formed in a hollow cylindrical shape. A target substance 267 is contained in the tank 261.

At least the inside of the tank 261 is made of a material that is less likely to react with the target substance 267. The material that is less likely to react with the target substance 267 may be, for example, any of SiC, SiO₂, Al₂O₃, molybdenum, tungsten, and tantalum.

The nozzle 262 is arranged at the bottom surface of the tank 261. One end of the pipe-shaped nozzle 262 is fixed to the hollow tank 261, and the other end is provided with a nozzle hole 262a. The tank 261 is located outside the chamber 2 and the nozzle hole 262a is located inside the chamber 2. That is, the tank 261 is arranged outside the target supply path 2a, and the nozzle 262 is arranged inside the target supply path 2a through the target supply hole 2b of the target supply path 2a. The target supply unit 26 is arranged at the end of the target supply path 2a, so that the target supply hole 2b is blocked. As a result, the inside of the chamber 2 is isolated from the atmosphere. The tank 261, the nozzle 262, the target supply path 2a, and the chamber 2 are in communication with each other.

At least the inner surface of the nozzle 262 is made of a material that is less likely to react with the target substance 267. The nozzle hole 262a is formed in a shape such that the molten target substance 267 is ejected into the chamber 2 in a jet form.

The plasma generation region 25 in the chamber 2 is located on the extension line of the center axis direction of the nozzle 262.

The target supply unit 26 includes a heater 711 and a heater power source 712 as a mechanism for adjusting the temperature of the tank 261. The heater 711 is fixed to an outer side surface portion of the tank 261 and heats the tank 261. The heater 711 is connected to the heater power source 712. The heater power source 712 supplies power to the heater 711.

The processor 5 includes an arithmetic control processor 51 and a trigger selection and delay device 53. The processor 5 functions as an EUV light generation control unit.

The heater power source 712 is connected to the arithmetic control processor 51, and power supply to the heater 711 is controlled by the arithmetic control processor 51.

A temperature sensor (not shown) is fixed to the outer side surface portion of the tank 261. The temperature sensor is connected to the arithmetic control processor 51. The temperature sensor detects the temperature of the tank 261 and outputs a detection signal to the arithmetic control processor 51. In order to heat and maintain the target substance 267 in the tank 261 to and at a predetermined temperature equal to or higher than the melting point, the arithmetic control processor 51 may adjust the power to be supplied to the heater 711 based on the detection signal from the temperature sensor. When the target substance 267 is tin, the predetermined temperature is equal to or higher than 231.93° C. being the melting point of tin and, for example, is 240° C. or higher and 290° C. or lower. The arithmetic control processor 51 controls the temperature of the target substance 267 to the predetermined temperature by adjusting a value of the current to be supplied from the heater power source 712 to the heater 711 based on an output from the temperature sensor.

The target supply unit 26 includes a pressure adjuster 721 that adjusts the pressure in the tank 261. The pressure adjuster 721 is connected to the tank 261 through a pipe 722. The pipe 722 may be covered with a heat insulating material (not shown) or the like. A heater (not shown) may be arranged at the pipe 722. The temperature of the pipe 722 may be maintained at substantially the same temperature as the temperature in the tank 261.

As described above, the pressure adjuster 721 is provided through a pipe 722 on a bottom surface portion of the cylindrical tank 261 on the opposite side to the nozzle 262.

The pressure adjuster 721 includes a solenoid valve for supplying and exhausting, a pressure sensor, and the like. The pressure adjuster 721 may detect the pressure in the tank 261 using the pressure sensor.

The pressure adjuster 721 is connected to a gas cylinder 723. The gas cylinder 723 is filled with an inert gas such as helium or argon. The gas cylinder 723 supplies the inert gas into the tank 261 through the pressure adjuster 721.

The pressure adjuster 721 is connected to an exhaust pump (not shown). The pressure adjuster 721 can operate an exhaust pump to exhaust the gas in the tank 261. The pressure adjuster 721 can increase or decrease the pressure in the tank 261 by supplying the gas into the tank 261 or exhausting the gas from the tank 261.

The pressure adjuster 721 is connected to the arithmetic control processor 51. The pressure adjuster 721 outputs a detection signal of the pressure detected by the pressure sensor to the arithmetic control processor 51. The pressure adjuster 721 receives a control signal output from the arithmetic control processor 51.

The control signal output from the arithmetic control processor 51 may be a control signal for controlling the operation of the pressure adjuster 721 based on the detection signal output from the pressure adjuster 721 so that the pressure in the tank 261 becomes a target pressure.

The pressure adjuster 721 supplies the gas into the tank 261 or exhausts the gas in the tank 261 based on the control signal from the arithmetic control processor 51. Accordingly, the pressure in the tank 261 can be adjusted to the target pressure.

The target supply unit 26 forms the droplet 271 by, for example, a continuous jet method. In the continuous jet method, the nozzle 262 is vibrated to give standing waves to the flow of the target 27 ejected in a jet form, thereby periodically separating the target 27. The separated target 27 may form a free interface by its surface tension to form the droplet 271.

The piezoelectric element 731 as a means for vibrating the nozzle 262 is fixed to an outer side surface portion of the pipe-shaped nozzle 262. The target supply unit 26 includes a piezoelectric drive circuit 732, and the piezoelectric element 731 is connected to the piezoelectric drive circuit 732. The piezoelectric drive circuit 732 supplies power to the piezoelectric element 731. The piezoelectric drive circuit 732 is connected to the arithmetic control processor 51. The arithmetic control processor 51 controls power supply to the piezoelectric element 731.

The flow of the target substance 267 ejected in a jet form from the nozzle 262 is periodically separated by the vibration of the piezoelectric element 731 to form the droplets 271.

The piezoelectric drive circuit 732 causes the piezoelectric element 731 to vibrate at a frequency f0 to generate the droplets 271 at 1/f0 cycle. The frequency f0 for driving the piezoelectric element 731 is referred to as a “piezoelectric frequency f0”. The piezoelectric frequency f0 is a droplet generation frequency, and may be referred to as a target generation frequency. The piezoelectric frequency f0 is, for example, about 180 kHz, and the droplet generation cycle (1/f0 cycle) is, for example, about 0.005 ms.

The description of the target 27 includes the concept of the droplet 271. A trajectory on which the target 27 output from the nozzle 262 moves toward the plasma generation region 25 is referred to as a target trajectory F. A direction in which the target 27 moves toward the plasma generation region 25 is referred to as a “target travel direction”. The target travel direction in FIG. 2 is the Y direction.

The target supply unit 26 is fixed to a stage 265 arranged at an end of the target supply path 2a. The stage 265 can move the target supply unit 26 in two axis directions being the X direction and the Z direction. The stage 265 may move the target supply unit 26 in a direction substantially perpendicular to the direction of the target trajectory F.

The stage 265 is connected to the arithmetic control processor 51. The stage 265 may receive a control signal output from the arithmetic control processor 51.

The control signal output from the arithmetic control processor 51 may be a control signal for adjusting the position of the target supply unit 26 so that the target 27 output into the chamber 2 reaches the target position.

The stage 265 may move the target supply unit 26 based on the control signal from the arithmetic control processor 51. Accordingly, the position of the target 27 output into the chamber 2 in the X direction and the Z direction can be adjusted so that the target 27 reaches the target position.

The target collection device 28 is arranged on an extension line in the direction in which the target 27 output into the chamber 2 travels.

The EUV light generation apparatus 1 includes a target passage detection device 70, a target image measurement device 90, and a pulse waveform processing unit 55. Each of the target passage detection device 70 and the target image measurement device 90 is an example of the target sensor 4.

The target passage detection device 70 detects the target 27 passing through a predetermined region in the chamber 2. The predetermined region for monitoring the passage of the target 27 is a region located between the nozzle hole 262a and the plasma generation region 25 and intersecting the target trajectory F.

The target passage detection device 70 is provided at a predetermined position on the side surface portion of the target supply path 2a. The target passage detection device 70 is located between the target supply unit 26 and the plasma generation region 25.

The target passage detection device 70 includes an illumination unit 71 and a measurement instrument 81. The illumination unit 71 and the measurement instrument 81 may be arranged to face each other across the target trajectory F. In FIG. 2, the direction in which the illumination unit 71 and the measurement instrument 81 face each other is substantially parallel to the X direction, but the present invention is not limited thereto.

The illumination unit 71 radiates illumination light, which is continuous light, to the droplet 271 traveling along the target trajectory F. The continuous light applied to the droplet 271 may be continuous laser light.

The illumination unit 71 includes an illumination light source 72, an illumination optical system 73, and a window 78. The window 78 is attached to the wall of the chamber 2. The illumination unit 71 is arranged outside the chamber 2 via the window 78. The illumination light source 72 may be, for example, a light source such as a continuous wave (CW) laser output unit that outputs continuous laser light. The beam diameter of the continuous laser light may be sufficiently larger than the diameter (e.g., 20 μm) of the droplet 271.

The illumination optical system 73 includes an optical element such as a lens. Not limited to a transmissive optical element such as a lens, the optical element may be a reflective optical element such as a mirror, or a combination thereof.

The illumination optical system 73 concentrates the continuous laser light radiated from the illumination light source 72 through the window 78 into a predetermined region including the target passage detection position on the target trajectory F. The predetermined region including the light concentration region of the illumination optical system 73 is referred to as a “target detection region”.

The illumination optical system 73 may include, for example, a cylindrical lens. The illumination optical system 73 may irradiate the target trajectory F with an elliptical beam. The length of the minor axis of the elliptical beam may be a length close to the diameter of the droplet 271, and the major axis may be in a direction perpendicular to the target trajectory F. For example, the minor axis direction of the elliptical beam may coincide with the Y direction, and the major axis direction may coincide with the Z direction. Note that the beam shape of the continuous laser light radiated from the illumination unit 71 may be a shape different from an ellipse.

When the droplet 271 traveling along the target trajectory F reaches the target detection region, the continuous laser light radiated from the illumination unit 71 illuminates the droplet 271.

The measurement instrument 81 receives the light radiated from the illumination unit 71 and detects the light intensity. The measurement instrument 81 includes a window 88, a filter 82, an imaging optical system 84, and an optical sensor 86. The window 88 is attached to the wall of the chamber 2. The measurement instrument 81 is arranged outside the chamber 2 via the window 88.

The imaging optical system 84 may be an optical system such as a collimator. The optical system such as the collimator may be configured by an optical element such as a lens. The imaging optical system 84 guides the continuous laser light radiated from the illumination unit 71 to the optical sensor 86 through the window 88 and the filter 82.

The optical sensor 86 may be a light receiving element including a photodiode. The optical sensor 86 may be a photodiode array including a plurality of sensor elements.

The optical sensor 86 outputs an electric signal corresponding to the amount of received light. The optical sensor 86 detects the light intensity of the continuous laser light guided by the imaging optical system 84.

When the droplet 271 passes through the predetermined region of the target trajectory F, a part of the continuous laser light is blocked by the droplet 271, and the light intensity (received light amount) received by the measurement instrument 81 decreases. The measurement instrument 81 outputs a detection signal corresponding to a change in the light intensity caused by the passage of the droplet 271 to the pulse waveform processing unit 55. Here, the detection signal corresponding to the change in the light intensity obtained from the optical sensor 86 may be referred to as a “target passage detection signal”.

The pulse waveform processing unit 55 receives the target passage detection signal output from the target passage detection device 70, and generates a target detection trigger signal from the target passage detection signal. The target detection trigger signal is a signal indicating a timing at which the target 27 has passed through the predetermined region of the target trajectory F.

The pulse waveform processing unit 55 outputs the target detection trigger signal to the trigger selection and delay device 53. Thus, the trigger selection and delay device 53 may detect the timing at which the target 27 traveling from the target supply unit 26 toward the plasma generation region 25 has passed through the predetermined region on the target trajectory F. The target passage detection device 70 is also referred to as a timing sensor. The pulse waveform processing unit 55 may be included in the processor 5.

The target image measurement device 90 captures an image of the target 27 supplied to the plasma generation region 25, and generates image data thereof. The target image measurement device 90 includes an illumination unit 91 and a measurement instrument 101. The illumination unit 91 and the measurement instrument 101 may be arranged to face each other across the target trajectory F. The direction in which the illumination unit 91 and the measurement instrument 101 face each other may be substantially perpendicular to the target trajectory F or may be non-perpendicular thereto.

The illumination unit 91 irradiates the target 27 traveling along the target trajectory F with pulse light.

The illumination unit 91 includes a flash lamp 92, an illumination optical system 94, and a window 98. The window 98 is attached to the wall of the chamber 2. The illumination unit 91 is arranged outside the chamber 2 via the window 98.

The flash lamp 92 is connected to the trigger selection and delay device 53. The flash lamp 92 emits pulse light pulsed based on a light emission trigger signal output from the trigger selection and delay device 53.

The illumination optical system 94 may be an optical system such as a collimator, and is configured by an optical element such as a lens. The illumination optical system 94 guides the pulse light emitted from the flash lamp 92 onto the target trajectory F through the window 98.

The illumination unit 91 may radiate the pulse light toward the target trajectory F based on the light emission trigger signal. The pulse light radiated from the illumination unit 91 is radiated to the target 27 traveling along the target trajectory F.

The measurement instrument 101 captures an image of the shadow of the target 27 irradiated with the pulse light by the illumination unit 91. The measurement instrument 101 includes a window 108, a filter 102, an imaging optical system 104, a shutter 105, an imaging optical system 106, and an image sensor 107. The window 108 is attached to the wall of the chamber 2. The measurement instrument 101 is arranged outside the chamber 2 via the window 108.

The imaging optical system 104 may be an optical element such as a pair of lenses. The shutter 105 may be an electrical shutter or a mechanical shutter. The shutter 105 is connected to the trigger selection and delay device 53. The shutter 105 opens and closes when the shutter trigger signal output from the trigger selection and delay device 53 is input, and regulates the exposure time of the image sensor 107.

The shutter 105 may be, for example, an image intensifier (IIU) capable of performing gate operation. The image intensifier includes a photoelectric surface, a microchannel plate (MCP), and a fluorescent surface. The photoelectric surface converts light into electrons. The MCP is an electron multiplication element that two-dimensionally detects electrons output from the photoelectric surface and multiplies the electrons. The gain can be adjusted by adjusting the voltage to be applied to the MCP. The fluorescent surface converts the electrons output from the output end of the MCP into light.

The gate operation of the image intensifier is achieved by changing the potential difference between the photoelectric surface and the input surface of the MCP. The gate operation is synonymous with shutter operation. When the potential of the photoelectric surface is lower than the potential of the input surface of the MCP, the electrons output from the photoelectric surface enter the MCP, and an output image is obtained from the fluorescent surface. The state of the gate ON corresponds to a state of “shutter open”. Further, when the potential of the photoelectric surface is higher than the potential of the input surface of the MCP, the electrons do not reach the MCP, so that no output image is obtained from the fluorescent surface. The state of the gate OFF corresponds to a state of “shutter closed”. For example, the gate operation can be performed by fixing the potential of the input surface of the MCP and applying a negative pulse voltage to the photoelectric surface.

The imaging optical system 104 and the imaging optical system 106 form an image of the shadow of the target 27 guided through the window 108 on the light receiving surface of the image sensor 107.

The image sensor 107 may be, for example, a two-dimensional image sensor such as a complementary metal oxide semiconductor (CMOS). The image sensor 107 captures an image of the shadow of the target 27 imaged by the imaging optical systems 104, 106.

The image sensor 107 is connected to the trigger selection and delay device 53 and the arithmetic control processor 51. The image sensor 107 captures the image of the shadow of the target 27 based on an imaging trigger signal from the trigger selection and delay device 53. The image sensor 107 may include a signal processing circuit that generates digital image data such as bitmap data from an image signal obtained by imaging.

The image data generated by using the image sensor 107 is transmitted to the arithmetic control processor 51.

The arithmetic control processor 51 calculates parameters related to the target 27 based on the image data obtained from the image sensor 107. Examples of the parameters related to the target 27 may include the size, velocity, position, target-to-target distance (interval) of the target 27. The target image measurement device 90 is commonly referred to as a “size sensor”.

The measurement instrument 101 may perform fixed-point observation of a specific range on the target trajectory F. The position of the droplet 271 imaged by the measurement instrument 101 in the Y direction may be a relative position within the imaging range in the target travel direction. In the captured image, the position of the target 27 in the Y direction may be the position of the target 27 in a direction substantially parallel to the target travel direction.

The interval of the target 27 is a distance between two adjacent targets 27 sequentially output from the target supply unit 26 into the chamber 2, and is the target-to-target distance in the target travel direction.

The trigger selection and delay device 53 generates various trigger signals based on the target detection trigger signal received from the pulse waveform processing unit 55. The trigger selection and delay device 53 adds appropriate delay times to the target detection trigger signal, and generates the imaging trigger signal, the shutter trigger signal, the light emission trigger signal, and the laser trigger signal.

The imaging trigger signal is a signal for controlling the imaging timing of the image sensor 107. The shutter trigger signal is a signal for controlling the opening and closing timing (operation timing) of the shutter 105. The light emission trigger signal is a signal for controlling the light emission timing of the flash lamp 92. The laser trigger signal is a signal for controlling the irradiation timing of the pulse laser light 33 of the laser device 3.

Further, the trigger selection and delay device 53 generates a target detection trigger signal for EUV light emission and a target detection trigger signal for image measurement by decimating the target detection trigger signal. The target detection trigger signal for EUV light emission is a signal for controlling the timing of generating EUV light. The target detection trigger signal for image measurement is a signal for controlling the timing at which the target image measurement device 90 performs target measurement.

The arithmetic control processor 51 transmits trigger selection information and delay data to the trigger selection and delay device 53. The trigger selection information includes information for selecting a trigger signal. The delay data includes information of a delay time required for generation of a corresponding trigger signal.

### 3.2 Operation

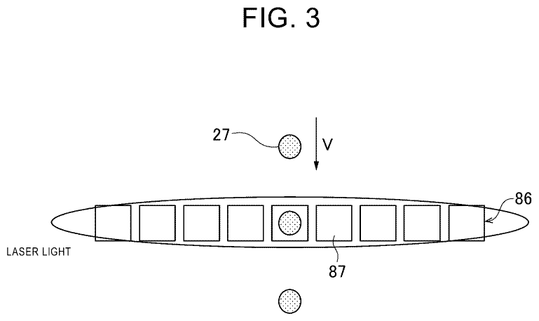

The operation of the target passage detection device 70 and the operation related to the trigger signal generation processing will be described with reference to FIGS. 3 to 6.

FIG. 3 shows an example of an image formed on the light receiving surface of the optical sensor 86 of the target passage detection device 70. The optical sensor 86 may be, for example, a photodiode array (PDA) module including a plurality of sensor elements 87. The shape of the light receiving surface of each of the plurality of sensor elements 87 may be a square or may be another shape such as a rectangle. Although FIG. 3 shows a PDA module in which nine sensor elements 87 are arranged in a row, the number and arrangement of the sensor elements 87 are not limited to the example shown in FIG. 3. The sensor element 87 is understood to be a pixel that performs photoelectric conversion.

An image of the elliptical beam of the laser light as the illumination light may be incident over the entire sensor elements 87. As the target 27 passes through the light concentration region of the elliptical beam, a shadow of the target 27 may be created on any of the plurality of sensor elements 87.

The diameter of the shadow of the target 27 may be smaller than the length of the side of the light receiving surface of the sensor element 87. The shadow of the target 27 may be an enlarged image of the target 27. The alignment direction of the plurality of sensor elements 87 may be substantially perpendicular to the target travel direction. Further, the arrangement direction of the plurality of sensor elements 87 may be substantially perpendicular to the normal direction of the light receiving surface. The normal direction of the light receiving surface may substantially coincide with the direction in which the laser light is incident.

In FIG. 3, the shadow of the target 27 passes through the light receiving surface of the sensor element 87 located in the center of the PDA module. The downward arrow in FIG. 3 indicates the target travel direction, and a velocity V of the target 27 is, for example, 45 m/s.

The movement direction of the shadow of the target 27 on the light receiving surface is determined by the positional relationship between the direction in which the illumination light is incident on the light receiving surface and the target trajectory F. Therefore, the movement direction of the shadow of the target 27 on the light receiving surface may not coincide with the movement direction of the target 27.

The target passage detection device 70 radiates the CW laser light having a sheet-like shape (elliptical beam shape) from the illumination unit 71 so as to pass through a position above the plasma generation region 25 by 2.5 mm. Here, the position above the plasma generation region 25 means the position on the upstream side of the target trajectory F in the target travel direction, that is, the position on the side close to the target supply unit 26.

The position above the plasma generation region 25 by 2.5 mm is an example of the position set as the target detection region. The laser light having passed through the position above the plasma generation region 25 by 2.5 mm passes through the imaging optical system 84 and enters the PDA module.

The imaging optical system 84 forms an image of the predetermined region including the position above the plasma generation region 25 by 2.5 mm on the sensor surface of the PDA module.

When the droplet 271 is not present in the target detection region, the laser light enters the PDA module without being blocked, and the PDA module outputs a constant detection signal corresponding to the light receiving amount. Here, the signal level of the “constant detection signal” is defined as the signal strength “100%”.

When the droplet 271 output at the piezoelectric frequency f0 (about 180 kHz) passes through the target detection region of the target passage detection device 70, the detection signal output from the PDA module decreases.

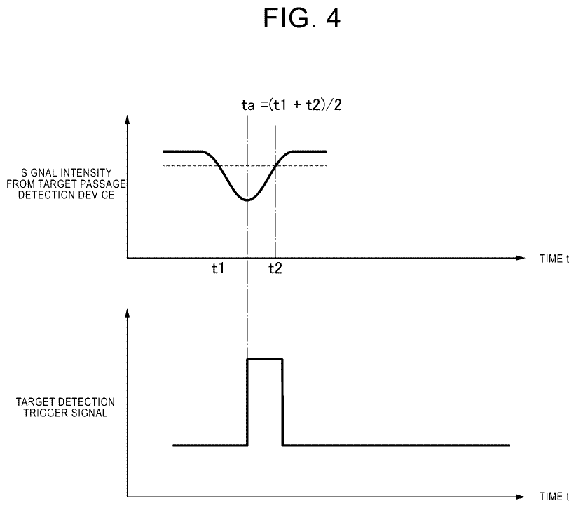

FIG. 4 shows an example of the detection signal output from the target passage detection device 70 and an example of the target detection trigger signal generated from the detection signal.

As shown at the upper stage of FIG. 4, the signal intensity of the detection signal output from the target passage detection device 70 decreases due to the passage of the target 27. When the target 27 moves out of the target detection region, the signal intensity of the detection signal recovers to the original 100% level.

The pulse waveform processing unit 55 uses the level at which the signal intensity of the detection signal is 100% as a reference, and detects a midpoint of t1 and t2 as the passage timing of the target 27, where t1 represents the timing at which the detection signal has decreased to a threshold set to a constant ratio with respect to a reference intensity and t2 represents the timing at which the decreased detection signal has recovered to the threshold. That is, when the passage timing is ta, ta is calculated by the following expression.

$$ta = ( t 1 + t 2 ) / 2$$

The timing of t1 is referred to as “signal drop timing”, and the timing of t2 is referred to as “signal recovery timing”. The threshold may be set to 90% of the reference intensity, for example. The dashed line in the graph at the upper stage of FIG. 4 indicates the level of the threshold.

As shown at the lower stage of FIG. 4, the pulse waveform processing unit 55 outputs the target detection trigger signal with reference to the passage timing ta.

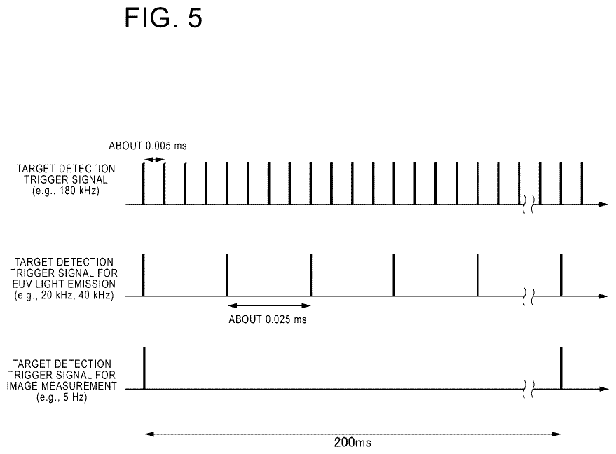

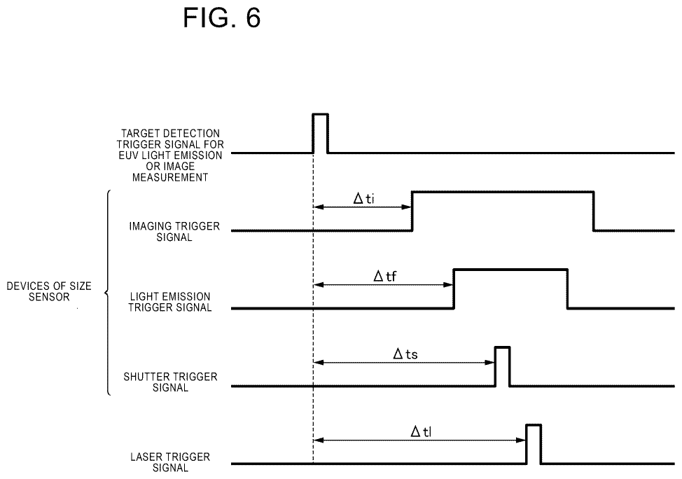

FIGS. 5 and 6 show an example of the generation timing of each trigger signal generated by the trigger selection and delay device 53.

The target detection trigger signal is shown at the upper stage of FIG. 5, the target detection trigger signal for EUV light emission is shown on the middle stage, and the target detection trigger signal for image measurement is shown on the lower stage.

The target detection trigger signal is generated, for example, for each of the droplets 271 generated at the piezoelectric frequency of about 180 kHz.

The trigger selection and delay device 53 receives the trigger selection information from the arithmetic control processor 51, and performs operation 1 and operation 2 described below based on the target detection trigger signal.

### [Operation 1]

Since the EUV light emission is performed, for example at about 20 kHz or 40 kHz, the trigger selection and delay device 53 generates the target detection trigger signal for EUV light emission by decimating the target detection trigger signal to have that frequency.

### [Operation 2]

Since the measurement of the target 27 by the target image measurement device 90 is performed, for example, at about 5 Hz, the trigger selection and delay device 53 further decimates the target detection signal for EUV light emission and generates the target detection trigger signal for image measurement.

FIG. 6 shows an example of the respective trigger signals being the target detection trigger signal for EUV light emission or the target detection trigger signal for image measurement, the imaging trigger signal, the light emission trigger signal, the shutter trigger signal, and the laser trigger signal from above.

The trigger selection and delay device 53 receives information of the delay time from the arithmetic control processor 51 and generates various trigger signals.

The information of the delay time received by the trigger selection and delay device 53 includes a delay time Δti to be applied to the imaging trigger signal, a delay time Δtf to be applied to the light emission trigger signal, a delay time Δts to be applied to the shutter trigger signal, and a delay time Δtl to be applied to the laser trigger signal.

The trigger selection and delay device 53 adds the delay time Δtl to the target detection trigger signal for EUV light emission to generate the laser trigger signal.

The trigger selection and delay device 53 adds the delay times Δti, Δtf, Δts for operating the target image measurement device 90 based on the image measurement target detection signal to generate the imaging trigger signal, the light emission trigger signal, and the shutter trigger signal, respectively.

The operation of periodically correcting the delay time based on the information obtained from the target image measurement device 90 is as follows.

First, as shown in FIG. 6, the image sensor 107 receives an imaging trigger signal generated as being delayed by Δti from the target detection trigger signal for image measurement, and starts exposure for a certain period of time.

The flash lamp 92 receives the light emission trigger signal generated as being delayed by Δtf from the target detection trigger signal for image measurement, and emits light for a certain period of time. The light emitted by the flash lamp 92 illuminates the plasma generation region 25, and the light having passed through the plasma generation region 25 reaches the shutter 105 through the imaging optical system 104.

The shutter 105 receives the shutter trigger signal generated as being delayed by Ats from the target detection trigger signal for image measurement, and applies a voltage for a certain period of time (the shutter 105 is opened).

The light having passed through the shutter 105 passes through the imaging optical system 106 and reaches the image sensor 107. By transferring the image of the plasma generation region 25 onto the image sensor 107 by the two imaging optical systems 104, 106, the image including the image of the shadow of the target 27 in the plasma generation region 25 is output from the image sensor 107.

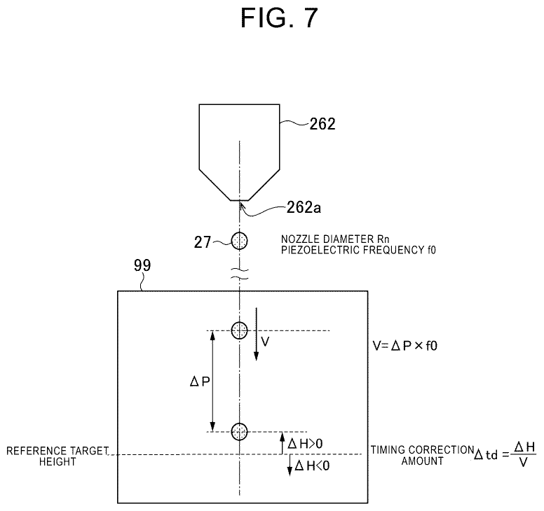

FIG. 7 schematically shows an example of an image 99 acquired via the image sensor 107. The image sensor 107 captures the image 99 including images of shadows of the plurality of targets 27 sequentially output from the nozzle 262. The arithmetic control processor 51 reads the image 99 output from the image sensor 107, performs image processing to obtain a target interval ΔP on the image 99, and calculates the target velocity V from the target interval ΔP and the piezoelectric frequency f0.

$$V = Δ P \times f 0 \qquad ( Expression 1 )$$

As specific values, for example, when the target interval ΔP is 250 μm and the piezoelectric frequency f0 is 180 kHz, the target velocity V is 45 m/s.

When the height of the target 27 on the output image 99 is deviated from the reference target height corresponding to the plasma generation region 25, the arithmetic control processor 51 calculates a deviation amount ΔH. The deviation amount ΔH is referred to as the “target height deviation ΔH”. The arithmetic control processor 51 calculates a timing deviation amount Δtd from the target height deviation ΔH and the target velocity V.

$$Δ td = Δ H / V \qquad ( Expression 2 )$$

The unit of the timing deviation amount Δtd is seconds (s), the unit of the target height deviation ΔH is meters (m), and the unit of the target velocity V is meter per second (m/s).

Here, the term “height” of the target 27 means a position in the target travel direction (Y direction). The targeted target 27 for which the target height deviation ΔH is calculated is the target 27 closest to the reference target height among the plurality of targets 27 included in the image 99. Here, ΔH is a positive value when the targeted target 27 is on the target supply unit 26 side with respect to the reference target height, and is a negative value when it is on the opposite side (the target collection device 28 side). The target height deviation ΔH is generated by a change in the target velocity V.

The timing deviation amount Δtd calculated by Expression 2 is the timing correction amount. The term of timing correction amount is synonymous with a timing correction time.

The arithmetic control processor 51 corrects the delay times Δti, Δtf, Δts, Δtl of the respective trigger signals by using the deviation amount Δtd, and transmits the corrected delay time information to the trigger selection and delay device 53.

That is, the arithmetic control processor 51 adds the deviation amount Δtd to the current delay time Δti to correct the delay time and calculate a new (corrected) delay time Δti.

$$Δ ti = Δ ti + Δ td$$

The left side of the expression represents the corrected delay time, and Δti on the right side represents the current (uncorrected) delay time.

Similarly, for the delay time Δtf of the light emission trigger signal, the delay time Δts of the shutter trigger signal, and the delay time Δtl of the laser trigger signal, the arithmetic control processor 51 calculates a new delay time for each of the above using the deviation amount Δtd.

$$\begin{matrix}Δ tf = Δ tf + Δ td \\ Δ ts = Δ ts + Δ td \\ Δ tl = Δ tl + Δ td\end{matrix}$$

Hereinafter, Δti, Δtf, Δts, and Δtl are collectively referred to as “Δti (or f, s, l)” for the sake of simplicity of description. The suffix “i (or f, s, l)” indicates that the suffix is any of “i”, “f”, “s”, and “l”.

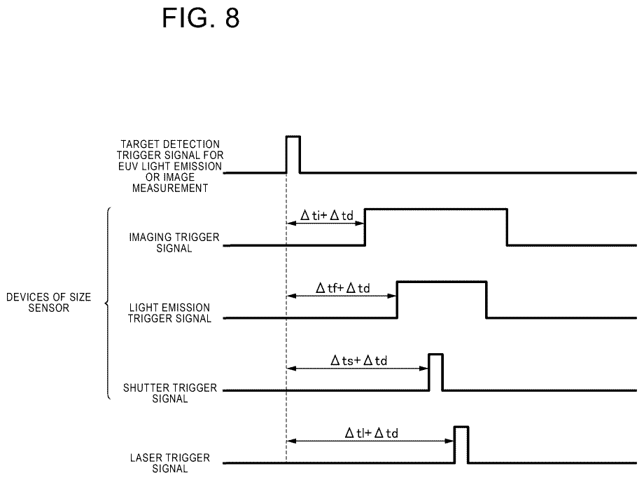

FIG. 8 is a timing chart showing the generation timing of each trigger signal whose delay time has been corrected.

The trigger selection and delay device 53 transmits each trigger signal to the corresponding device at the timing ti (or f, s, l) obtained by adding the corrected delay time Δti (or f, s, l) of each trigger signal to the target detection trigger signal for EUV light emission or the target detection trigger signal for image measurement in synchronization with the passage timing ta of the target 27.

$$ti ( or f , s , l ) = ta + Δ ti ( or f , s , l )$$

The trigger selection and delay device 53 performs operation with Δti (or f, s, l) fixed until the next periodic correction of the delay time Δti (or f, s, l).

### 4. Problem

In the EUV light generation apparatus 1 according to the comparative example, since the correction of the deviation of the irradiation timing of the pulse laser light 33 due to the velocity change of the target 27 is performed using the processing result of the image 99 obtained by the target image measurement device 90, the correction frequency of the timing deviation is performed at the acquisition frequency of the image 99 being a low frequency of, for example, 5 Hz (at imaging intervals of 200 ms).

However, the velocity of the target 27 also changes during the imaging interval of 200 ms by the target image measurement device 90, and in the EUV light generation apparatus 1 according to the comparative example, the deviation of the irradiation timing cannot be sufficiently corrected.

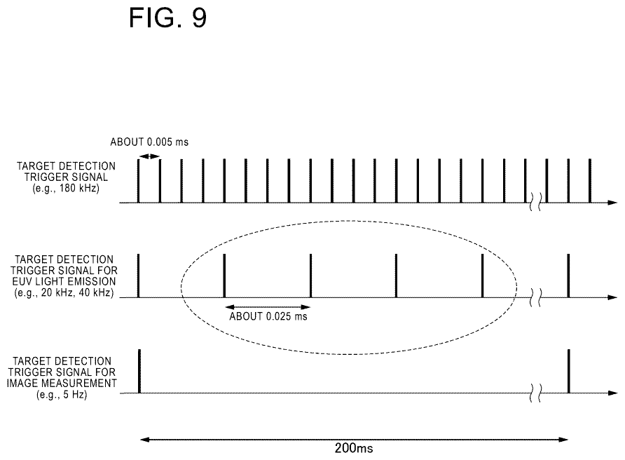

That is, since the target 27 during the imaging interval 200 ms cannot be measured by the target image measurement device 90 as in the period surrounded by a broken line ellipse in FIG. 9, it is not possible to correct the deviation of the irradiation timing caused by the velocity change of the target 27 used for EUV light generation within this period.

The above causes deterioration in EUV light emission performance, such as a decrease in the energy conversion efficiency (Conversion Efficiency: CE) and a variation increase in EUV light energy. Further, contamination of the EUV light concentrating mirror 23 occurs due to occurrence of fragments caused by the relative positional deviation between the target 27 and the irradiation position of the pulse laser light 33.

### 5. First Embodiment

### 5.1 Configuration

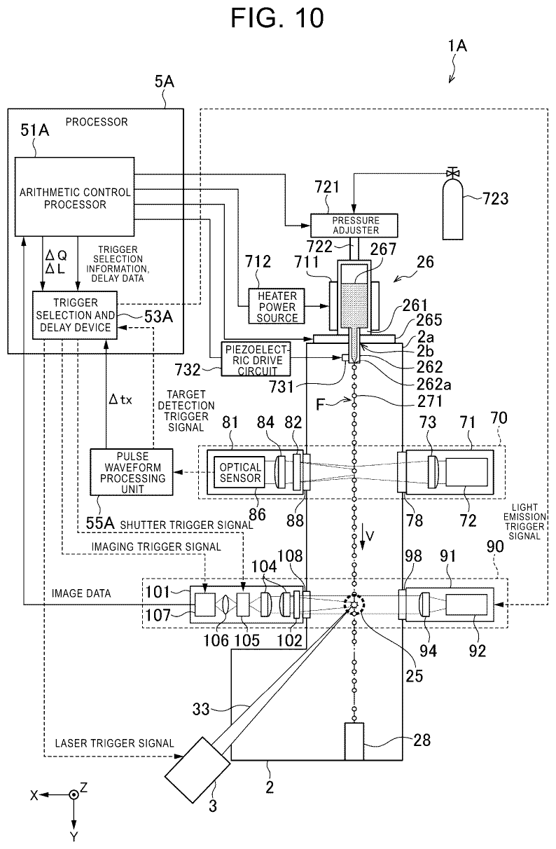

FIG. 10 shows the configuration of an EUV light generation apparatus 1A according to a first embodiment. The configuration of the EUV light generation apparatus 1A shown in FIG. 10 will be described in terms of differences from the configuration of the EUV light generation apparatus 1 shown in FIG. 2.

The EUV light generation apparatus 1A includes a pulse waveform processing unit 55A and a processor 5A instead of the pulse waveform processing unit 55 and the processor 5 of FIG. 2. The processor 5A includes an arithmetic control processor 51A and a trigger selection and delay device 53A.

In the EUV light generation apparatus 1A, the target passage detection device 70 (timing sensor) is used to measure the velocity change of the target 27, and the timing deviation due to the velocity change is corrected.

The pulse waveform processing unit 55A calculates a new time width Δtx during the target passage from the waveform of the detection signal obtained from the target passage detection device 70. The time width Δtx may be, for example, a time width from the signal drop timing t1 to the signal recovery timing t2 (Δtx=t2−t1).

The trigger selection and delay device 53A calculates a timing correction amount Δtad based on a distance ΔQ from the target passage detection height to the reference target height, a distance ΔL by which the target 27 moves from the target position where the detection signal output from the target passage detection device 70 falls below a threshold th to the target position where the detection signal recovers to the threshold th, and the time width Δtx, and updates the timing correction amount Δtad. The trigger selection and delay device 53A updates the delay time Δti (or f, s, l) of each trigger signal by updating the timing correction amount Δtad. The distance ΔL is referred to as the velocity coefficient. Other configurations may be similar to those in FIG. 2.

### 5.2 Operation

In the first embodiment, the delay time Δti (or f, s, l) of each trigger signal is newly decomposed and defined as Expression 3 below.

Δti (or f, s, l)=Δtai (or f, s, l)+Δtad (Expression 3) where Δtai (or f, s, l) is an individual delay time for the operation of each device. Here, Δtai is a delay time for the operation of the image sensor 107, Δtaf is a delay time for the operation of the flash lamp 92, Δtas is a delay time for the operation of the shutter 105, and Δtal is a delay time for the operation of the laser device 3. Further, Atai (or f, s, l) is a fixed value and is a negative value.

Further, Δtad is a time that the target 27 takes for moving the distance ΔQ from the target passage detection height to the reference target height. Here, Δtad is referred to as a timing correction amount.

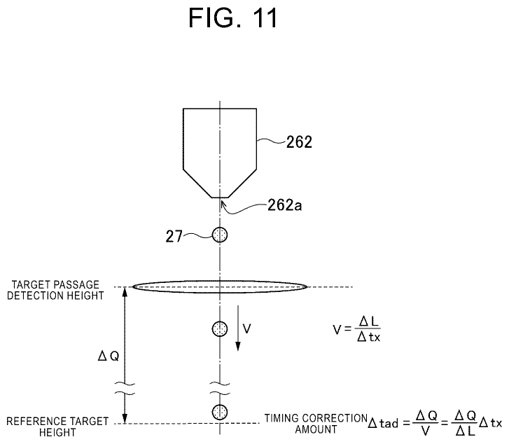

FIG. 11 is an explanatory diagram showing a calculation method of the timing correction amount Δtad according to the first embodiment. The target passage detection height shown in FIG. 11 is the height of the target detection region in which the target 27 is detected by the target passage detection device 70, and is the height where the target trajectory F is irradiated with the CW laser light from the illumination unit 71.

The target 27 output from the nozzle hole 262a of the nozzle 262 travels toward the plasma generation region 25. The distance ΔQ from the target passage detection height to the reference target height in the plasma generation region 25 is a fixed value. The target velocity V may vary among the targets 27. The reference target height may or may not be the same as a plasma generation height that is targeted. Preferably, the reference target height is approximately the same as the plasma generation height that is targeted.

The reference target height is an example of the “reference position” in the present disclosure.

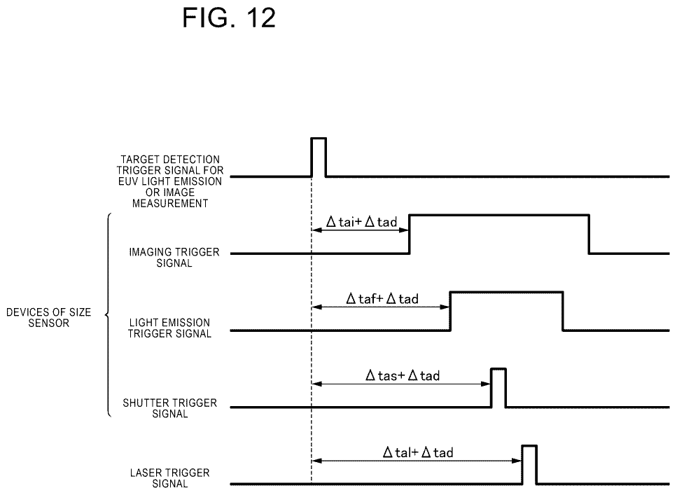

FIG. 12 shows an example of the generation timing of each trigger signal generated by the trigger selection and delay device 53A. Similarly to FIG. 6, FIG. 12 shows an example of the respective trigger signals being the target detection trigger signal for EUV light emission or the target detection trigger signal for image measurement, the imaging trigger signal, the light emission trigger signal, the shutter trigger signal, and the laser trigger signal. FIG. 12 is different from FIG. 6 in that the delay time of each trigger signal is defined by Expression 3.

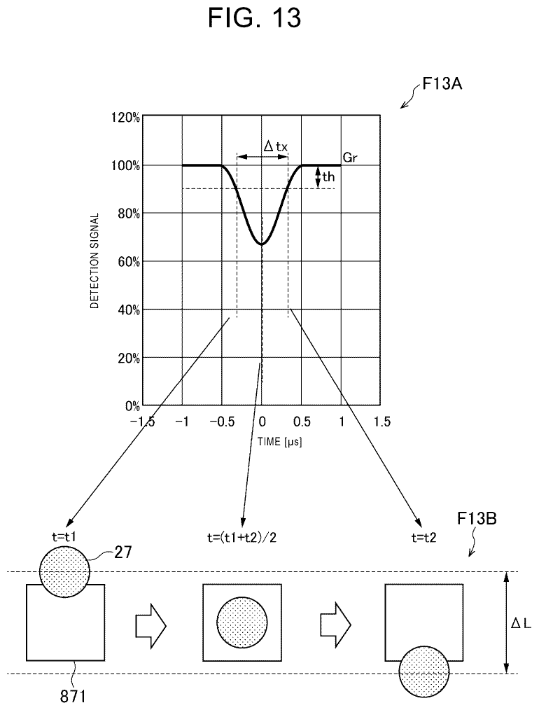

FIG. 13 is an explanatory diagram of operation of the pulse waveform processing unit 55A. The graph F13A shown at the upper stage of FIG. 13 shows an example of the detection signal obtained from the target passage detection device 70. A waveform Gr indicated by a thick line in the graph F13A indicates a temporal change in the signal intensity of the detection signal. FIG. F13B at the lower stage of FIG. 13 is a schematic diagram showing a relative positional relationship between the target 27 moving in the target travel direction and the light receiving surface of the sensor element 871 in time series.

As described with reference to FIG. 4, the pulse waveform processing unit 55A calculates the passage timing ta based on the detection signal obtained from the target passage detection device 70. The timing indicated by t1 is an example of the “first timing” in the present disclosure, and the timing indicated by t2 is an example of the “second timing” in the present disclosure.

The pulse waveform processing unit 55A compares the detection signal output from the target passage detection device 70 with the threshold th, and calculates the time width Δtx from the signal drop timing t1, which is a time point at which the detection signal falls below the threshold th, to the signal recovery timing t2, which is a time point at which the detection signal recovers to the threshold th.

$$Δ tx = t 2 - t 1 \qquad ( Expression 4 )$$

The time width Δtx corresponds to a time width during which the detection signal is below the threshold th.

The trigger selection and delay device 53A calculates the target velocity V by using the distance ΔL by which the target 27 moves from the target position where the detection signal of the target passage detection device 70 falls below the threshold th to the target position where the detection signal recovers to the threshold th, and the time width Δtx, and calculates the target velocity V.

$$V = Δ L / Δ tx \qquad ( Expression 5 )$$

The target position where the detection signal falls below the threshold th corresponds to the position of the target 27 at the time of the signal drop timing t1. The target position where the detection signal recovers to the threshold th corresponds to the position of the target 27 at the time of the signal recovery timing t2. As shown in FIG. 13, the distance ΔL is a fixed value determined from the relationship among the size of the light receiving surface of the sensor element 871, the diameter of the target 27, and the threshold th. The distance ΔL is referred to as the velocity coefficient ΔL.

The trigger selection and delay device 53A calculates the timing correction amount Δtad based on the target velocity V calculated by Expression 5 and the distance ΔQ acquired from the arithmetic control processor 51A.

$$Δ tad = Δ Q / V = Δ Q / ( Δ L / Δ tx ) \qquad ( Expression 6 )$$

Here, Δtad is always a positive value.

The trigger selection and delay device 53A updates the delay time Δti (or f, s, l) of each trigger signal of Expression 3 using the calculated timing correction amount Δtad.

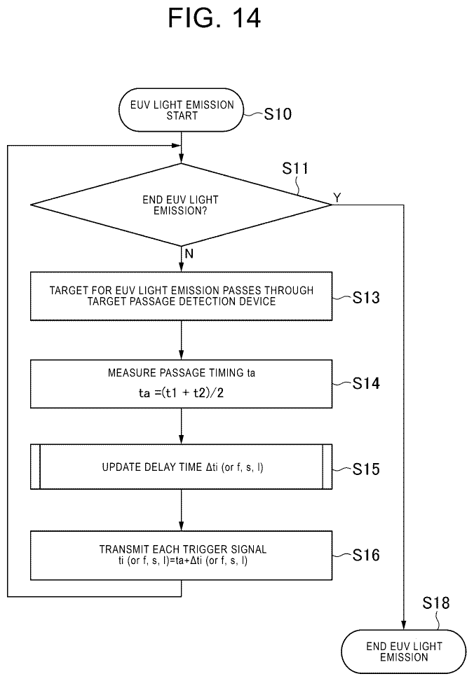

FIG. 14 is a flowchart showing an example of the operation related to timing correction of each trigger signal in the EUV light generation apparatus 1A. The operation of the processor 5A and the pulse waveform processing unit 55A will be described with reference to FIG. 14. FIG. 14 shows an example of processing performed on the target 27 for EUV light emission.

In step S10, the processor 5A starts EUV light emission.

In step S11, the processor 5A determines whether or not to end EUV light emission. When the determination result of step S11 is NO, processing proceeds to step S13.

In step S13, the target 27 for EUV light emission passes through the target detection region of the target passage detection device 70.

In step S14, the pulse waveform processing unit 55A measures the passage timing ta from the detection signal output from the target passage detection device 70 in a similar manner as in FIG. 4. That is, the pulse waveform processing unit 55A measures the midpoint of the signal drop timing t1 and the signal recovery timing t2 as the passage timing ta. Instead of obtaining the passage timing ta from t1 and t2, a time point (lower peak point) at which the detection signal of FIG. 13 is minimized may be detected as the passage timing ta.

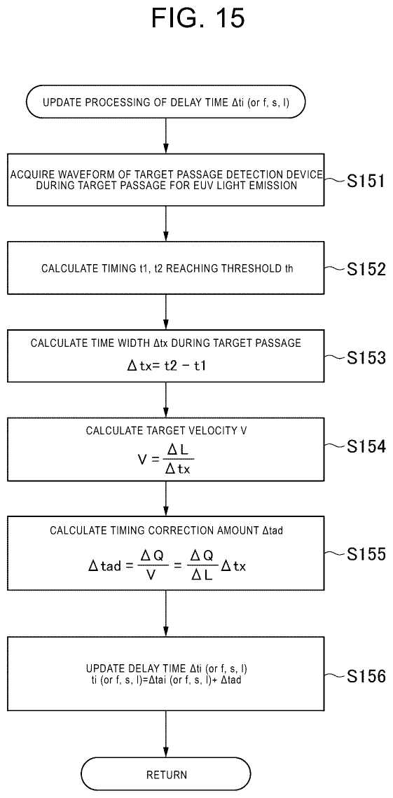

In step S15, the trigger selection and delay device 53A performs the update processing of the delay time Δti (or f, s, l). The process applied to step S15 will be described later with reference to FIG. 15.

In step S16, the trigger selection and delay device 53A transmits each trigger signal generated by using the delay time Δti (or f, s, l) updated in step S15 to the corresponding device. The trigger selection and delay device 53A transmits, to the corresponding device, each trigger signal at a timing obtained by adding the delay time Δti (or f, s, l) updated in step S15 to the passage timing ta in synchronization with the passage timing ta of the target 27.

The trigger selection and delay device 53A transmits the respective trigger signals ti (or f, s, l) at the timings described below.

$$ti ( or f , s , l ) = ta + Δ ti ( or f , s , l )$$

After step S16, processing returns to step S11.

When the determination result of step S11 is YES, processing proceeds to step S18, and the processor 5 ends EUV light emission.

FIG. 15 is a flowchart of a subroutine of the update processing of each delay time applied to step S15 of FIG. 14. When the process of step S15 is started, in step S151, the pulse waveform processing unit 55A acquires the waveform of the detection signal of the target passage detection device 70 during the target passage for EUV light emission.

In step S152, the pulse waveform processing unit 55A compares the detection signal of the target passage detection device 70 with the threshold th, and calculates the timing t1 at which the detection signal falls below the threshold th and the timing t2 at which the detection signal recovers to the threshold th.

In step S153, the pulse waveform processing unit 55A calculates the time width Δtx during the target passage from the timings t1, t2. The pulse waveform processing unit 55A calculates the time width Δtx by Expression 4.

In step S154, the trigger selection and delay device 53A calculates the target velocity V from the time width Δtx and the velocity coefficient ΔL. The trigger selection and delay device 53A calculates the target velocity V by Expression 5.

In step S155, the trigger selection and delay device 53A calculates the timing correction amount Δtad from the target velocity V and the distance ΔQ. The trigger selection and delay device 53A calculates the timing correction amount Δtad by Expression 6.

As is apparent from Expression 6, the process of step S154 may be included in the process of step S155. That is, the trigger selection and delay device 53A is understood to substantially calculate the target velocity V by calculating (ΔQ/ΔL)Δtx in step S155.

In step S156, the trigger selection and delay device 53A updates the delay time Δti (or f, s, l) of each trigger signal by Expression 3.

After step S156, processing returns to the flowchart of FIG. 14.

The transmission frequency of the trigger signal may be different for each device. For example, the laser trigger signal tl may be transmitted at a frequency of 20 kHz, while the imaging trigger signal ti may be transmitted at a frequency of 5 Hz.

5.3 Relationship Between Detection Signal Obtained from Target Passage Detection Device and Threshold

Although FIG. 13 shows an example in which the detection signal decreases due to the passage of the target 27, the detection signal obtained from the target passage detection device 70 is not limited to this example, and the detection signal may be increased due to the passage of the target 27. For example, the detection signal shown in FIG. 13 may be inverted to generate a detection signal in which the signal increases due to the passage of the target 27. In this case, the time width Δtx is calculated from the timing t1 of exceeding the threshold th and the timing t2 of recovering to the threshold th.

As exemplified in FIG. 13, when the detection signal decreases due to the passage of the target 27, the timing t1 falling below the threshold th is an example of the “timing exceeding the threshold” in the present disclosure. The description of “exceeding the threshold” includes the concept of crossing and falling below the threshold th, as in FIG. 13.

### 5.4 Effect

According to the EUV light generation apparatus 1A of the first embodiment, it is possible to correct the laser irradiation timing of the successive targets 27 to be used for EUV light emission, so that a decrease in EUV light emission performance due to the velocity change of the target 27 can be suppressed. Further, according to the EUV light generation apparatus 1A, occurrence of fragments caused by the relative positional deviation between the target 27 and the pulse laser light 33 can be suppressed, and contamination of the EUV light concentrating mirror 23 can be suppressed.

### 6. Second Embodiment

### 6.1 Configuration

The configuration of the EUV light generation apparatus according to a second embodiment is similar to that of the EUV light generation apparatus 1A, but different from the first embodiment in the following points.

That is, in the EUV light generation apparatus 1A according to the second embodiment, the target height deviation ΔH, which is the difference from the targeted target position (reference target height) of the target 27, is calculated by image processing from the target image captured by the target image measurement device 90, and the velocity coefficient ΔL in the first embodiment is corrected based on ΔH.

When the target image is captured by the target image measurement device 90 after the timing adjustment of the trigger signal is performed by the timing correction amount Δtad determined in the first embodiment, the target 27 on the image and the targeted target position may slightly deviate from each other.

This is because the detection signal output from the target passage detection device 70 varies due to a change in the size of the target 27 or a change in the target passage position, and therefore, when a constant (fixed value) velocity coefficient ΔL is used, the target velocity V cannot be accurately obtained from the time width Δtx by Expression 5, and deviation occurs in the target height (position of the target 27) in the plasma generation region 25.

### 6.2 Operation

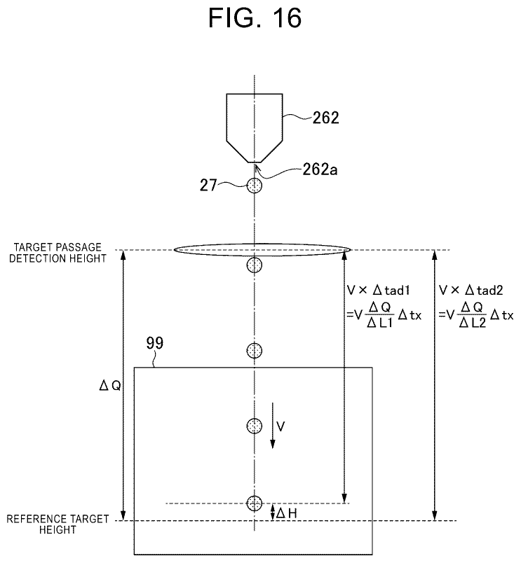

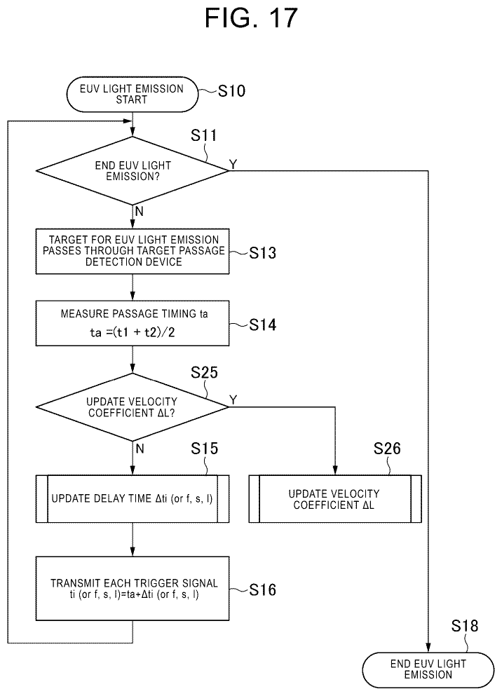

FIG. 16 is an explanatory diagram of the update processing of the velocity coefficient ΔL in the EUV light generation apparatus 1A according to the second embodiment.

The arithmetic control processor 51A obtains the target height deviation ΔH from the image 99 measured by the target image measurement device 90, updates the velocity coefficient ΔL by the Expression 7 below, and transmits the updated velocity coefficient ΔL to the trigger selection and delay device 53A.

$$Δ L = ( Δ Q - Δ H ) \times Δ L / Δ Q \qquad ( Expression 7 )$$

Here, ΔL on the left side of Expression 7 represents the velocity coefficient after the update (after the correction), and ΔL on the right side represents the velocity coefficient before the update (current).

The update processing of the velocity coefficient ΔL may be performed only when the calculation of ΔH by the target image measurement device 90 is performed.

In the following, derivation of Expression 7 will be described.

When the target height deviation ΔH occurs in the image 99 captured by the target image measurement device 90 after updating the timing correction amount Δtad1 with the velocity coefficient represented by ΔL1, the distance (ΔQ-ΔH) by which the target 27 travels within the time of the timing correction amount Δtad1 (=ΔQ×Δtx/ΔL1) is expressed by Expression 8 below with the velocity of the target 27 represented by V.

$$Δ Q - Δ H = V \times Δ Q \times Δ tx / Δ L 1 \qquad ( Expression 8 )$$

When it is assumed, for the target 27 having the same velocity V, that the target height deviation ΔH does not occur in the image 99 after updating the timing correction amount Δtad with the velocity coefficient represented by ΔL2, the distance ΔQ by which the target 27 travels within the time of the timing correction amount Δtad2(=ΔQ×Δtx/ΔL2) is expressed by Expression 9 below.

$$Δ Q = V \times Δ Q \times Δ tx / Δ L 2 \qquad ( Expression 9 )$$

From Expressions 8 and 9, the velocity coefficient ΔL2 corrected so that ΔH becomes zero is expressed by Expression below using the immediately preceding velocity coefficient ΔL1.

$$Δ L 2 = ( Δ Q - Δ H ) \times Δ L / Δ Q \qquad ( Expression 10 )$$

Therefore, from the result of Expression 10, when the velocity coefficient ΔL is updated by Expression 7, the target height deviation ΔH is eliminated.

FIG. 17 is a flowchart showing an example of the operation related to timing correction of each trigger signal in the EUV light generation apparatus 1A according to the second embodiment. The flowchart of FIG. 14 will be described in terms of differences from FIG. 17.

In FIG. 17, step S25 is added between step S14 and step S15, and step S26 branched in parallel from step S25 is added.

In step S25, the arithmetic control processor 51A determines whether or not to update the velocity coefficient ΔL. When the determination result of step S25 is YES, the process of S26 is performed in parallel.

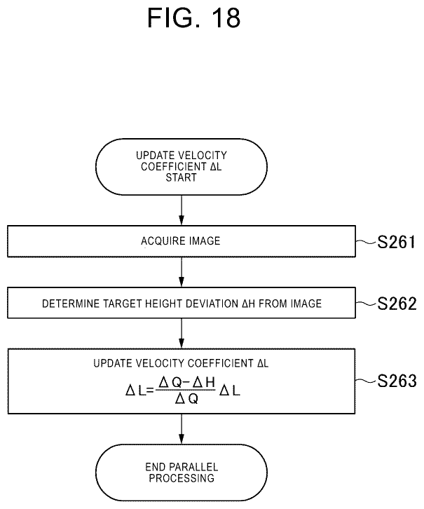

In step S26, the update processing of the velocity coefficient ΔL is performed. The process applied to step S26 will be described later with reference to FIG. 18. After step S26, step S26 is completed and the parallel processing ends. The process of step S26 is performed in parallel with processes in steps S11 to S16.

When the determination result of step S25 is NO, processing proceeds to step S15. Other steps are similar to those in FIG. 14.

FIG. 18 is a flowchart showing a subroutine of the update processing of the velocity coefficient ΔL applied to step S26 of FIG. 17.

When the parallel processing of step S26 is started, in step S261, the arithmetic control processor 51A acquires the image 99 obtained by imaging the target 27 with the target image measurement device 90.

In step S262, the arithmetic control processor 51A determines the target height deviation ΔH from the acquired image 99.

In step S263, the arithmetic control processor 51A updates the velocity coefficient ΔL by Expression 7. The arithmetic control processor 51A transmits the updated velocity coefficient ΔL to the trigger selection and delay device 53A.

After step S263, the parallel processing of step S26 is completed, and only the loop processing of steps S11 to S16 is performed.

### 6.3 Effect

According to the second embodiment, by periodically updating the velocity coefficient ΔL based on the image 99 obtained from the target image measurement device 90, it is possible to correct the target height deviation ΔH caused by the change in the size of the target 27 and a target passage position dy.

### 7. Third Embodiment

### 7.1 Configuration

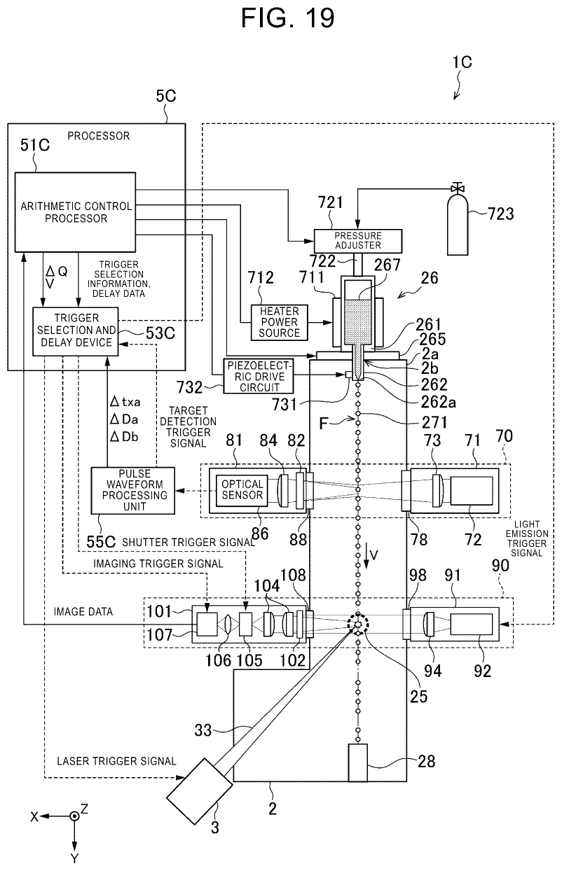

FIG. 19 shows the configuration of an EUV light generation apparatus 1C according to a third embodiment. The configuration of the EUV light generation apparatus 1C will be described in terms of differences from the configuration of the EUV light generation apparatus 1A.

The EUV light generation apparatus 1C includes a pulse waveform processing unit 55C and a processor 5C instead of the pulse waveform processing unit 55A and the processor 5A of FIG. 10. The processor 5C includes an arithmetic control processor 51C and a trigger selection and delay device 53C.

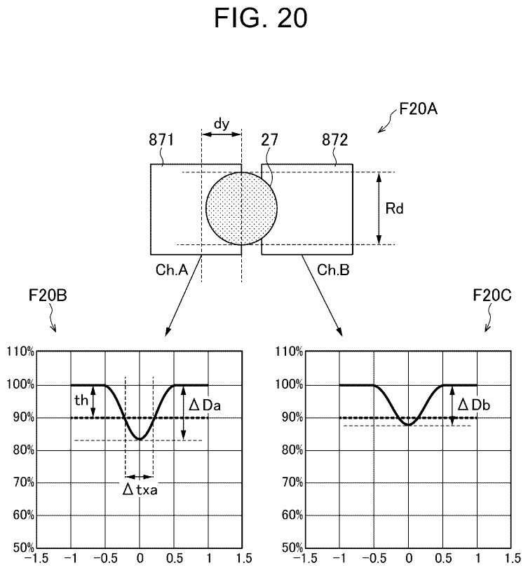

The EUV light generation apparatus 1C is different from the EUV light generation apparatus 1A in that a database defining the relationship among a target diameter Rd, a target passage position d, a passage signal height ΔDa, a passage signal height ΔDb, and the velocity coefficient ΔL is created (see FIGS. 20 and 23 to 25) and the process of correcting the velocity coefficient ΔL is performed using the database. The target diameter Rd is an example of an index indicating the size of the target 27.

Other configurations may be similar to those of the EUV light generation apparatus 1A.

### 7.2 Operation

### 7.2.1 Creation of Database

FIG. 20 is an explanatory diagram of various parameters used in the EUV light generation apparatus 1C. FIG. F20A at the upper stage of FIG. 20 schematically shows an image of the target 27 formed on the light receiving surfaces of two adjacent sensor elements 871, 872 of the optical sensor 86 in the target passage detection device 70. Let the sensor element 871 be a channel A (Ch. A) and the sensor element 872 be a channel B (Ch. B). The sensor element 871 is an example of the “first sensor element” in the present disclosure, and the sensor element 872 is an example of the “second sensor element” in the present disclosure. The term of “being adjacent” is an example of “adjacent” in the present disclosure.

The arrangement direction of the sensor elements 871, 872 may be, for example, the Z direction. The direction in which the target 27 moves is, for example, the Y direction. The Y direction is an example of the “first direction” in the present disclosure, and the Z direction is an example of the “second direction” in the present disclosure. The optical sensor 86 including the sensor elements 871, 872 is an example of the “sensor” in the present disclosure.

The graph F20B on the left at the lower stage of FIG. 20 shows the detection signal obtained from the sensor element 871. The graph F20C on the right at the lower stage of FIG. 20 shows the detection signal obtained from the sensor element 871. The detection signal (graph F20B) output from the sensor element 871 is an example of the “first signal” in the present disclosure, and the detection signal (graph F20C) output from the sensor element 872 is an example of the “second signal” in the present disclosure.

The target passage position dy is a passage position of the target 27 in the arrangement direction (for example, the Z direction) of the sensor elements 871, 872 and, is defined, with reference to the center of the sensor element 871, as a distance from the center of the sensor element 871 to the center of the target 27. The target passage position dy can be changed by moving the stage 265.

The target diameter Rd indicates the diameter of the target 27.

The EUV light generation apparatus 1C performs Process 1 to Process 4 to create the database.

### [Process 1]

The arithmetic control processor 51C measures the target 27 by the target passage detection device 70 while changing the piezoelectric frequency f0 of the target supply unit 26 and the target passage position dy, and calculates a time width Δtxa and the passage signal heights ΔDa, ΔDb from the detection signals of the two adjacent sensor elements 871, 872 of the target passage detection device 70 by the pulse waveform processing unit 55C. Here, Ada is equal to or more than ΔDb.

The target diameter Rd is changed by Expression 11 below by adjusting the piezoelectric frequency f0, where Rn is the nozzle diameter.

$${R}_{d} = \sqrt[3]{\frac{3 {R}_{n}^{2} V}{2 {f}_{0}}} \qquad ( Expression 11 )$$

As shown in FIG. 20, the passage signal height ΔDa is the difference in height between the highest value and the lowest value of the detection signal of the sensor element 871. The passage signal height ΔDb is the difference in height between the lowest value and the highest value of the signal of the sensor element 872. The “passage signal height” may be understood as the peak height of the detection signal. The term “peak height” is not limited to the peak height on the peak side, and includes the concept of the peak height on the valley side as shown in FIG. 20. Here, ΔDa is an example of the “first signal height” in the present disclosure, and ΔDb is an example of the “second signal height” in the present disclosure.

The time width Δtxa is calculated as the time during which the detection signal of the sensor element 871 falls below (exceeds) the threshold th. The method of calculating the time width Δtxa is similar to the method of calculating the time width Δtx described with reference to FIG. 13. The time width Δtxa is an example of the “first time width” in the present disclosure.

### [Process 2]

The arithmetic control processor 51C performs Process 1, obtains the target velocity V from the target interval ΔP of the image 99 acquired by the target image measurement device 90 and the piezoelectric frequency f0 by Expression 1, and transmits the target velocity V to the trigger selection and delay device 53C.

### [Process 3]

The trigger selection and delay device 53C obtains the velocity coefficient ΔL from the time width Δtxa and the target velocity V.

$$Δ L = V \times Δ txa \qquad ( Expression 12 )$$

### [Process 4]

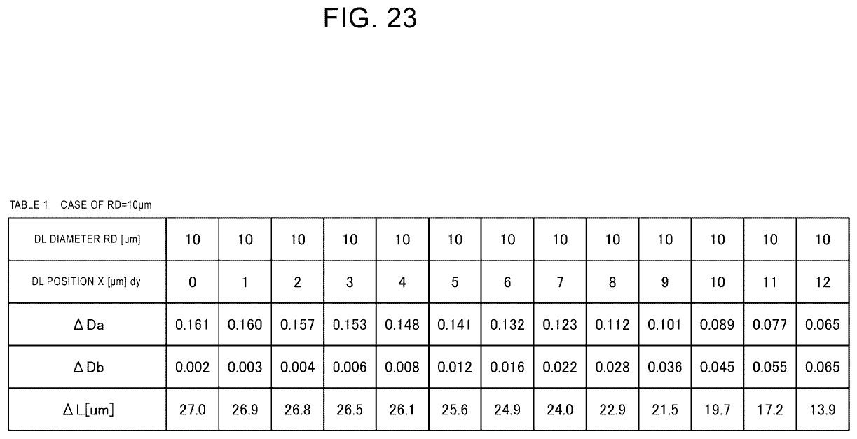

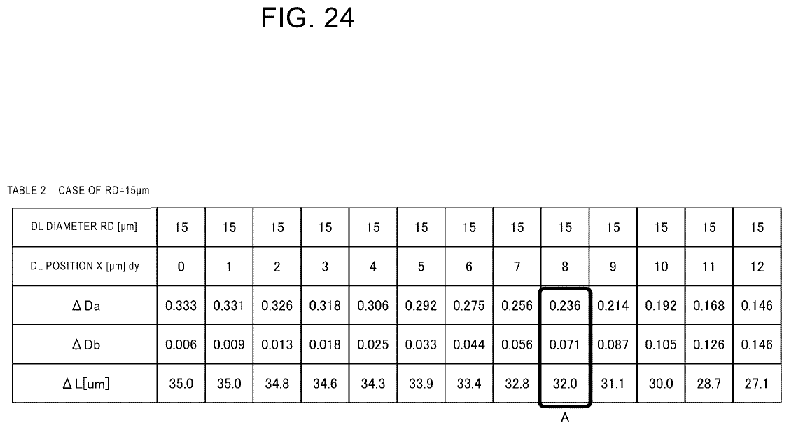

The trigger selection and delay device 53C stores in advance the relationship among ΔDa, ΔDb, and ΔL when dy and Rd are changed by Processes 1 to 4 described above as a database (see FIGS. 23 to 25).

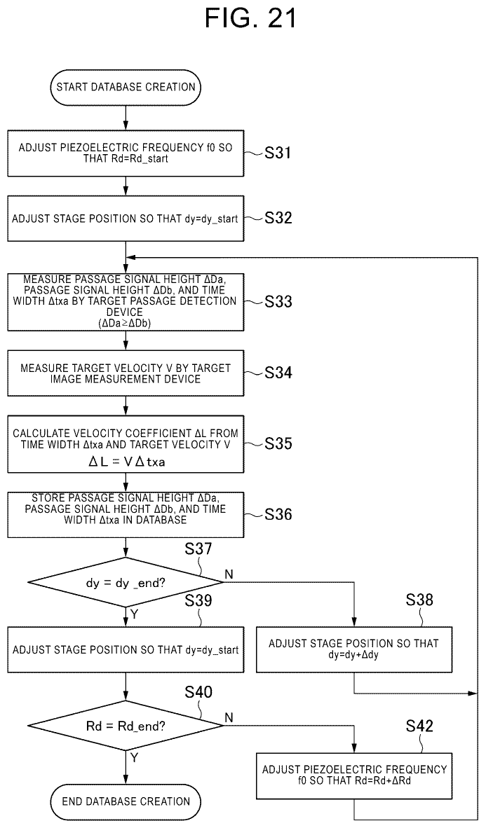

FIG. 21 is a flowchart showing flow of a database creation processing in the EUV light generation apparatus 1C.

Here, description is provided on an example in which ΔDa, ΔDb, and ΔL are obtained while the target diameter Rd is changed by a predetermined change amount ΔRd from an initial value Rd_start to a final value Rd_end and the target passage position dy is changed by a predetermined change amount Δdy from an initial value dy_start to a final value dy_end.

In step S31, the arithmetic control processor 51C adjusts the piezoelectric frequency f0 so that the target diameter Rd becomes the initial value Rd_start. Here, Rd_start may be, for example, 12 μm.

In step S32, the arithmetic control processor 51C adjusts the position of the stage 265 so that the target passage position dy becomes the initial value dy_start. Here, dy_start may be, for example, 0 μm.

In step S33, the pulse waveform processing unit 55C measures the passage signal height ΔDa, the passage signal height ΔDb, and the time width Δtxa based on the detection signals obtained from the two adjacent sensor elements 871, 872 of the target passage detection device 70.

In step S34, the arithmetic control processor 51C measures the target velocity V from the image 99 obtained from the target image measurement device 90.

In step 535, the trigger selection and delay device 53C calculates the velocity coefficient ΔL from the time width Δtxa and the target velocity V by Expression 12.

In step 536, the trigger selection and delay device 53C stores the values of the passage signal height ΔDa, the passage signal height ΔDb, and the velocity coefficient ΔL in the database in association with dy and Rd.

In step S37, the arithmetic control processor 51C determines whether or not dy matches dy_end. When the determination result of step S37 is NO, processing proceeds to step S38. In step S38, the arithmetic control processor 51C adds a predetermined change amount Δdy to the current value of dy to update the value of dy, and adjusts the position of the stage 265 such that dy=dy+Δdy is satisfied. The change amount Δdy may be, for example, 1 μm. After step S38, processing returns to step S33.

When the determination result of step S37 is YES, that is, when dy has reached dy_end, processing proceeds to step S39.

In step S39, the arithmetic control processor 51C adjusts the position of the stage 265 such that dy=dy_start is satisfied.

In step S40 after step S39, the arithmetic control processor 51C determines whether or not the target diameter Rd matches the final value Rd_end. When the determination result of step S40 is NO, processing proceeds to step S42.

In step S42, the arithmetic control processor 51C adds the predetermined change amount ΔRd to the current value of Rd to update the value of Rd and adjusts the piezoelectric frequency f0 such that Rd=Rd+Δrd is satisfied. The change amount ΔRd may be, for example, 1 μm. After step S42, processing returns to step S33.

The processes from step S33 to step S42 are repeated until Rd matches Rd_end. When the determination result of step S40 is YES, the database creation processing ends.

Here, the database creation processing shown in the flowchart of FIG. 21 is performed in the preparatory stage without performing EUV light emission.

The database thus created is used in determining the delay times of the respective trigger signals in the operation at the time of EUV light emission. Here, such database is not required to be created for each individual of the EUV light generation apparatus 1C, and only required to be created for each model thereof. The database created by the EUV light generation apparatus 1C of the same model can be applied to other individuals of the same model.

### 7.2.2 Operation for EUV Light Emission

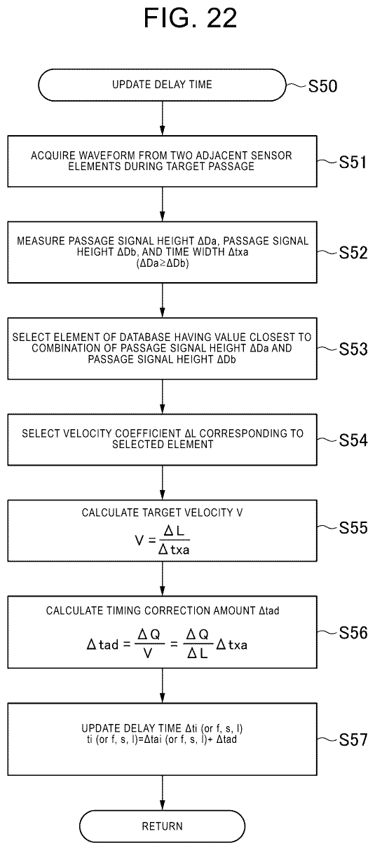

Next, the operation for EUV light emission will be described. FIG. 22 is a flowchart showing an example of update processing of each delay time of the corresponding trigger signal performed at the time of EUV light emission according to the third embodiment.

The update processing of each delay time shown in FIG. 22 may be applied to step S15 shown in FIG. 14.

In step 550, the update processing of each delay time is started.

In step S51, the pulse waveform processing unit 55C acquires the waveforms of the detection signals of the two adjacent sensor elements 87 during the target passage from the target passage detection device 70.

In step S52, the pulse waveform processing unit 55C measures the passage signal heights ΔDa, ΔDb and the time width Δtxa from the detection signals obtained from the two sensor elements 87. Here, Ada is equal to or more than ΔDb.

The two sensor elements 87 may be, for example, any two adjacent sensor elements 87 of the nine sensor elements 87 shown in FIG. 3.

In step S53, the trigger selection and delay device 53C selects an element of the database having a value closest to the combination of the passage signal height ΔDa and the passage signal height ΔDb. A specific example of step S53 will be described later with reference to FIG. 26.

In step S54, the trigger selection and delay device 53C selects the velocity coefficient ΔL corresponding to the selected element from the database.

In step S55, the trigger selection and delay device 53C calculates the target velocity V from the time width Δtxa and the velocity coefficient ΔL selected from the database.

$$V = Δ L / Δ txa \qquad ( Expression 13 )$$

In step S56, the trigger selection and delay device 53C calculates the timing correction amount Δtad from the distance ΔQ and the target velocity V using Expression 6.

In step S57, the trigger selection and delay device 53C updates the delay time Δti (or f, s, l) by Expression 3 using the calculated timing correction amount Δtad.

After step S57, processing returns to the flowchart of FIG. 14.

### 7.2.3 Specific Examples

FIGS. 23 to 25 show examples of the database created by the EUV light generation apparatus 1C. Tables 1 to 3, as shown in FIGS. 23 to 25, show the data of ΔDa, ΔDb, and ΔL when the target passage position dy is changed in the range of 10 to 20 μm by 3 levels in 5 μm steps and the target diameter Rd is changed in the range of 12 to 18 μm by 7 levels in 1 μm steps.

FIG. 26 is a graph obtained from the database of FIGS. 23 to 25. In FIG. 26, the horizontal axis represents the value of the passage signal height ΔDa or ΔDb, and the vertical axis represents the value of the velocity coefficient ΔL.

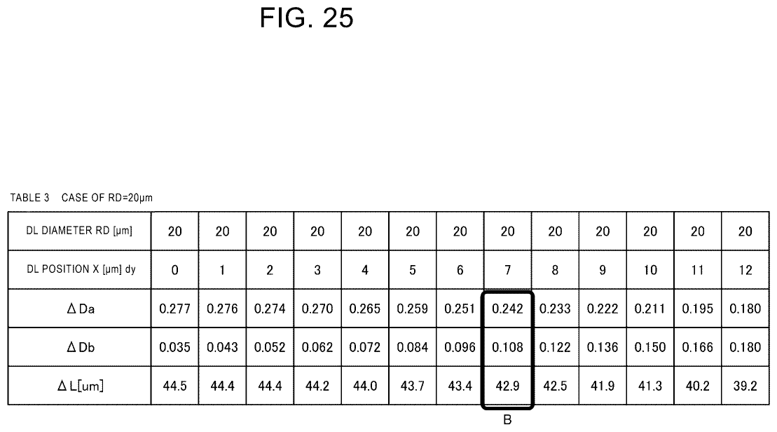

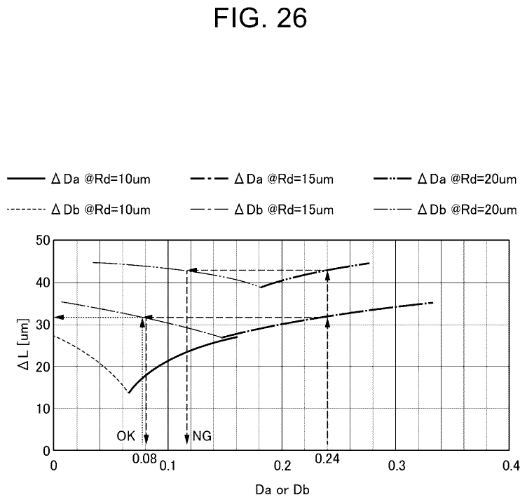

For example, description will be provided on the case in which the values of ΔDa and ΔDb obtained in step S52 are 0.24 and 0.08, respectively. In this case, when the database is referred to as focusing on the value of ΔDa, a portion surrounded by a frame line indicated by a reference numeral A in FIG. 24 and a portion surrounded by a frame line indicated by a reference numeral B in FIG. 25 are extracted as being close to ΔDa=0.24. Among the above, as focusing on the value of ΔDb, a portion indicated by the reference numeral A in FIG. 24 is closer to ΔDb=0.08.

Therefore, the trigger selection and delay device 53C selects the element of the velocity coefficient ΔL of the portion indicated by the reference numeral A from the database shown in FIG. 24. That is, 32.0 μm is applied as the value of the velocity coefficient ΔL.

### 7.3 Effect

According to the third embodiment, the velocity coefficient ΔL can be updated only by the information from the target passage detection device 70 without waiting for the measurement by the target image measurement device 90. Therefore, according to the third embodiment, the deviation of the target height due to the change of the target diameter Rd or the target passage position dy can be corrected at a high frequency.

### 8. Fourth Embodiment

### 8.1 Configuration

The configuration of the EUV light generation apparatus according to a fourth embodiment may be similar to that of the EUV light generation apparatus 1A shown in FIG. 10. The EUV light generation apparatus according to the fourth embodiment is different from the first embodiment in that the outputs of two adjacent sensor elements 87 of the target passage detection device 70 are coupled and the sum thereof is output.

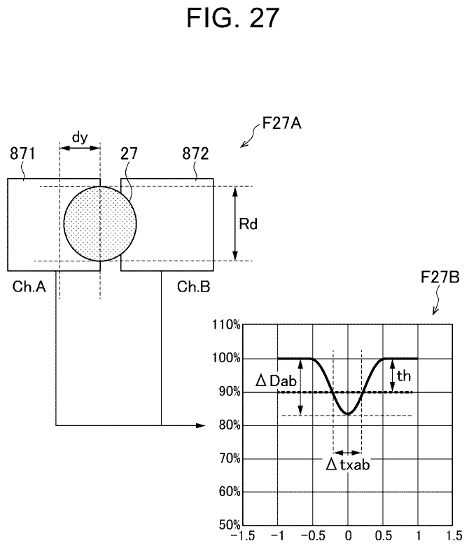

FIG. 27 is an explanatory diagram of a target detection signal obtained by coupling the outputs of two adjacent sensor elements 871, 872. FIG. F27A at the upper stage of FIG. 27 schematically shows an image of the target 27 formed on the light receiving surfaces of two adjacent sensor elements 871, 872 of the optical sensor 86 in the target passage detection device 70.

The graph F27B shown at the lower stage of FIG. 27 is an example of the target passage signal obtained by coupling the output signal of the sensor element 871 and the output signal of the sensor element 872. The target passage signal shown in the graph F27B is an example of the “sum signal” in the present disclosure. The passage signal height ΔDab is an example of the “peak height of the sum signal” in the present disclosure.

### 8.2 Operation

The pulse waveform processing unit 55A measures the passage signal height ΔDab from the coupled target passage signal, and calculates a time width Δtxab of the target passage signal with the threshold th being a constant ratio C with respect to ΔDab.

$$th = C \times Δ Dab \qquad ( Expression 14 )$$

The ratio C may be, for example, a constant of 0.05 to 0.9.

That is, the threshold th may be set to any value that is not less than 5% and not more than 90% of the passage signal height ΔDab.

The trigger selection and delay device 53A calculates the timing correction amount Δtad in a similar manner as in the first embodiment using the time width Δtxab, and corrects the laser irradiation timing and the like.

### 8.3 Effect

According to the fourth embodiment, by coupling the outputs of the two adjacent sensor elements 87, the velocity coefficient ΔL is not affected by the change in the target passage position dy. Further, as shown in Expression 14, since the threshold th is updated as the constant ratio C with respect to the passage signal height ΔDab of the coupled target passage signal, the velocity coefficient ΔL is not affected by the change in the target diameter Rd.

For the above reason, in the fourth embodiment, the velocity coefficient ΔL is not required to be updated with respect to the change in the target passage position dy and the change in the target diameter Rd.

### 9. Electronic Device Manufacturing Method

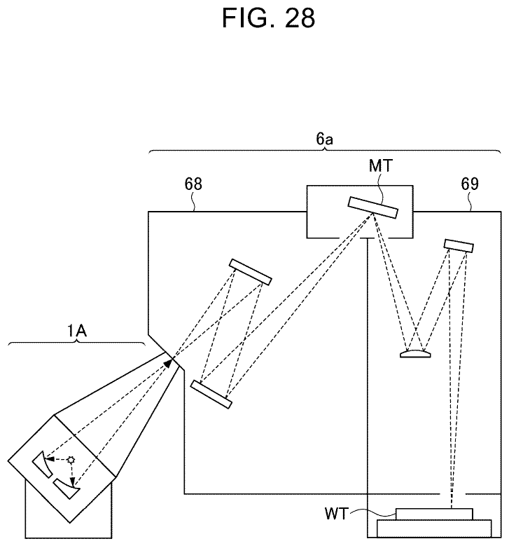

FIG. 28 schematically shows the configuration of an exposure apparatus 6a connected to the EUV light generation apparatus 1A. In FIG. 28, the exposure apparatus 6a as the external apparatus includes a mask irradiation unit 68 and a workpiece irradiation unit 69. The mask irradiation unit 68 illuminates, via a reflection optical system, a mask pattern of the mask table MT with the EUV light incident from the EUV light generation apparatus 1A. The workpiece irradiation unit 69 images the EUV light reflected by the mask table MT onto a workpiece (not shown) arranged on a workpiece table WT via the reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

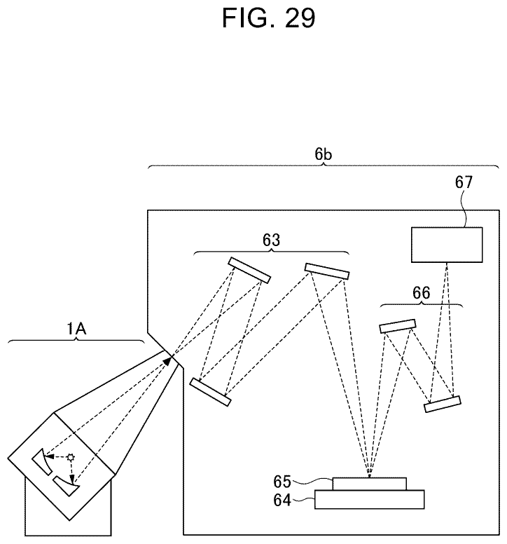

FIG. 29 schematically shows the configuration of an inspection apparatus 6b connected to the EUV light generation apparatus 1A. In FIG. 29, the inspection apparatus 6b as the external apparatus includes an illumination optical system 63 and a detection optical system 66. The illumination optical system 63 reflects the EUV light incident from the EUV light generation apparatus 1A to illuminate a mask 65 placed on a mask stage 64. Here, the mask 65 conceptually includes a mask blanks before a pattern is formed. The detection optical system 66 reflects the EUV light from the illuminated mask 65 and forms an image on a light receiving surface of a detector 67. The detector 67 having received the EUV light obtains an image of the mask 65. The detector 67 is, for example, a time delay integration (TDI) camera. Inspection for a defect of the mask 65 is performed based on the image of the mask 65 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 6a.

Instead of the EUV light generation apparatus 1A in FIGS. 28 and 29, the EUV light generation apparatus 1C can be used.

### 10. Processor

The processor such as the processor 5 and the arithmetic control processors 51, 51A, 51C may be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

The arithmetic control processors 51A, 51C, the trigger selection and delay devices 53A, 53C, and the pulse waveform processing units 55A, 55C shown in FIGS. 10 and 19 may perform, in order to perform the processing described in the embodiments, arithmetic processing using a processor and a memory after performing digitization using an analog electric signal processing circuit or an AD converter.

Further, processing may be performed by dividing into a plurality of processing devices with respect to dividing of processing functions different from the above, or may be performed by aggregating into one processing device. For example, the arithmetic control processor 51A and the trigger selection and delay device 53A may perform processing as being aggregated into one processing device. Such selections are appropriately performed in accordance with the speed and accuracy of the processing.

### 11. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation system configured to generate plasma by irradiating a target with pulse laser light and generate extreme ultraviolet light, comprising:
a chamber;
a target supply unit configured to supply the target into the chamber;
a target passage detection device configured to detect the target passing through a predetermined region;
a laser device configured to radiate the pulse laser light toward the target having passed through the predetermined region; and
a processor,
the target passage detection device including a light source configured to irradiate the predetermined region with light, and a sensor configured to receive the light and output a signal corresponding to a received light amount of the light, and
the processor acquiring, from the signal, a passage timing at which the target is detected and a time width during which the target is detected, and determining irradiation timing of the laser device for irradiating with the pulse laser light based on the passage timing and the time width.

2. The extreme ultraviolet light generation system according to claim 1,
wherein the processor compares the signal with a threshold and obtains, as the time width, a period during which the signal exceeds the threshold.

3. The extreme ultraviolet light generation system according to claim 1,
wherein the processor calculates a velocity of the target using the time width, and determines the irradiation timing based on a distance between the predetermined region and a reference position and the velocity of the target.

4. The extreme ultraviolet light generation system according to claim 3,
wherein a distance of movement of the target in a period from when the signal exceeds a threshold to when the signal recovers to the threshold due to the passage of the target is defined as a velocity coefficient, and
the processor calculates the velocity of the target from the velocity coefficient and the time width.

5. The extreme ultraviolet light generation system according to claim 4,
comprising an image sensor configured to image a region including the reference position,
wherein the processor updates the velocity coefficient based on a difference between a position of the target acquired using the image sensor and the reference position.

6. The extreme ultraviolet light generation system according to claim 5,
wherein the reference position is set in a plasma generation region in which the plasma is to be generated.

7. The extreme ultraviolet light generation system according to claim 5, comprising:
a flash lamp configured to illuminate the target in the region imaged by the image sensor; and
a shutter configured to regulate an exposure time to the image sensor,
wherein the processor determines at least one of an imaging timing of the image sensor, a light emission timing of the flash lamp, and an operation timing of the shutter based on the passage timing and the time width.

8. The extreme ultraviolet light generation system according to claim 1, comprising:
wherein the sensor includes a first sensor element, and a second sensor element adjacent to the first sensor element,
a light receiving surface of each of the first sensor element and the second sensor element is arranged in a second direction different from a first direction in which the target moves, and
the signal includes a first signal output from the first sensor element and corresponding to a received light amount of the light, and a second signal output from the second sensor element and corresponding to a received light amount of the light.

9. The extreme ultraviolet light generation system according to claim 8,
comprising a memory in which a relationship among a velocity coefficient, a first signal height indicating a peak height of the first signal, and a second signal height indicating a peak height of the second signal during the passage of the target through the predetermined region is previously stored, the velocity coefficient being defined as a distance of movement of the target in a period from when the signal exceeds a threshold to when the signal recovers to the threshold due to the passage of the target,
wherein the processor obtains, from the first signal and the second signal obtained from the sensor, the first signal height, the second signal height, and a first time width during which the first signal exceeds a threshold; obtains, from the relationship stored in the memory, the velocity coefficient corresponding to a combination of the first signal height and the second signal height; calculates a velocity of the target from the obtained velocity coefficient and the obtained first time width; and determines the irradiation timing based on a distance between the predetermined region and a reference position and the velocity of the target.

10. The extreme ultraviolet light generation system according to claim 9,
wherein the relationship stored in the memory is previously obtained while changing a size of the target and a passage position of the target in the second direction in the predetermined region.

11. The extreme ultraviolet light generation system according to claim 8,
wherein the processor acquires a sum signal of the first signal and the second signal and acquires, as the time width, a period during which the sum signal exceeds a threshold as comparing the sum signal and the threshold.

12. The extreme ultraviolet light generation system according to claim 11,
wherein the threshold is set with reference to a peak height of the sum signal.

13. The extreme ultraviolet light generation system according to claim 11,
wherein the threshold is 5% or more and 90% or less of a peak height of the sum signal.

14. The extreme ultraviolet light generation system according to claim 1,
wherein the processor sets the passage timing at a midpoint between a first timing at which the signal exceeds a threshold due to the passage of the target through the predetermined region, and a second timing at which the signal recovers to the threshold.

15. The extreme ultraviolet light generation system according to claim 1,
wherein the processor calculates a timing correction amount Δtad specifying the irradiation timing by an expression of Δtad=(ΔQ/ΔL)×Δtx
where a distance between the predetermined region and a reference position is ΔQ, the time width is Δtx, and a velocity coefficient indicating a distance of movement of the target in a period of the time width Δtx is ΔL.

16. An electronic device manufacturing method, comprising:
generating extreme ultraviolet light using an extreme ultraviolet light generation system;
outputting the extreme ultraviolet light to an exposure apparatus; and
exposing a photosensitive substrate to the extreme ultraviolet light in the exposure apparatus to manufacture an electronic device,
the extreme ultraviolet light generation system being configured to generate plasma by irradiating a target with pulse laser light and generate the extreme ultraviolet light, and including:
a chamber;
a target supply unit configured to supply the target into the chamber;
a target passage detection device configured to detect the target passing through a predetermined region;
a laser device configured to radiate the pulse laser light toward the target having passed through the predetermined region; and
a processor,
the target passage detection device including a light source configured to irradiate the predetermined region with light, and a sensor configured to receive the light and output a signal corresponding to a received light amount of the light, and
the processor acquiring, from a signal, a passage timing at which the target is detected and a time width during which the target is detected, and determining irradiation timing of a laser device for irradiating with pulse laser light based on the passage timing and the time width.

17. An electronic device manufacturing method, comprising:
inspecting a defect of a mask by irradiating the mask with extreme ultraviolet light generated by an extreme ultraviolet light generation system;
selecting a mask using a result of the inspection; and
exposing and transferring a pattern formed on the selected mask onto a photosensitive substrate,
the extreme ultraviolet light generation system being configured to generate plasma by irradiating a target with pulse laser light and generate the extreme ultraviolet light, and including:
a chamber;
a target supply unit configured to supply the target into the chamber;
a target passage detection device configured to detect the target passing through a predetermined region;
a laser device configured to radiate the pulse laser light toward the target having passed through the predetermined region; and
a processor,
the target passage detection device including a light source configured to irradiate the predetermined region with light, and a sensor configured to receive the light and output a signal corresponding to a received light amount of the light, and
the processor acquiring, from a signal, a passage timing at which the target is detected and a time width during which the target is detected, and determining irradiation timing of a laser device for irradiating with pulse laser light based on the passage timing and the time width.
